(19) United States
(12) Patent Application Publication
(10) Pub. No.: US 2026/0033354 A1
(43) Pub. Date: Jan. 29, 2026

(54) SEMICONDUCTOR PACKAGE

(71) Applicant: Samsung Electronics Co., Ltd., Suwon-si (KR)

(72) Inventor: Hyejin KIM, Suwon-si (KR)

(73) Assignee: Samsung Electronics Co., Ltd., Suwon-si (KR)

(21) Appl. No.: 19/024,650

(22) Filed: Jan. 16, 2025

(30) Foreign Application Priority Data
Jul. 25, 2024 (KR) 10-2024-0098922

(51) Int. Cl. H01L 23/00; H01L 23/538; H01L 25/07

(52) U.S. Cl. CPC H01L 24/48; H01L 23/5386; H01L 24/85; H01L 25/074; H01L 2224/48228; H01L 2224/85138; H01L 2225/0651; H01L 2225/06562

(57) ABSTRACT

A semiconductor package includes a semiconductor die stack stacked in a staircase shape; a wiring structure facing one surface of the semiconductor die stack, the wiring structure including a conductive pad facing the semiconductor die stack; and a bonding wire connecting the semiconductor die stack to the conductive pad. The wiring structure includes a wiring structure upper surface facing the one surface of the semiconductor die stack, and a wiring structure lower surface that is opposite the wiring structure upper surface, and the wiring structure upper surface extends along a virtual plane. The conductive pad includes a conductive pad surface facing the one surface of the semiconductor die stack. The conductive pad surface is separated from the virtual plane.

### CROSS-REFERENCE TO RELATED APPLICATION

This application is based on and claims priority under 35 U.S.C. § 119 to Korean Patent Application No. 10-2024-0098922, filed on Jul. 25, 2024, in the Korean Intellectual Property Office, the disclosure of which is incorporated by reference herein in its entirety.

### BACKGROUND

The inventive concepts relate to semiconductor packages, and more particularly, to semiconductor packages including semiconductor die stacks.

Along with the rapid development of the electronics industry and demands of users, electronic devices have been gradually miniaturized and lightened. Along with the miniaturization and lightening of electronic devices, semiconductor packages used therein also have been miniaturized and lightened. Accordingly, it may be advantageous to stack semiconductor dies included in a semiconductor package and easily connect the semiconductor dies to bonding wires, to provide semiconductor packages having high reliability.

### SUMMARY

Some example embodiments of the inventive concepts provide a semiconductor package including a plurality of semiconductor die stacks and a bonding wire group capable of easily connecting the plurality of semiconductor die stacks to a printed circuit board.

Some example embodiments of the inventive concepts provide a semiconductor package that includes a semiconductor die stack stacked in a staircase shape; a wiring structure facing one surface of the semiconductor die stack, the wiring structure including a conductive pad facing the semiconductor die stack; and a bonding wire connecting the semiconductor die stack to the conductive pad. The wiring structure includes a wiring structure upper surface and a wiring structure lower surface, the wiring structure upper surface facing the one surface of the semiconductor die stack, and the wiring structure lower surface opposite to the wiring structure upper surface, and the wiring structure upper surface extends along a virtual plane. The conductive pad includes a conductive pad surface facing the one surface of the semiconductor die stack. The conductive pad surface is separated from the virtual plane in a direction perpendicular to the conductive pad surface.

Some example embodiments of the inventive concepts further provide a semiconductor package that includes a semiconductor die stack having a plurality of semiconductor dies stacked in a staircase shape in a first horizontal direction; an upper semiconductor die stack on the semiconductor die stack, the upper semiconductor die stack having a plurality of upper semiconductor dies stacked in a staircase shape in a second horizontal direction that is opposite to the first horizontal direction; a wiring structure facing one surface of the semiconductor die stack, the wiring structure including conductive pads facing the semiconductor die stack; and bonding wires connecting the upper semiconductor die stack and the semiconductor die stack to the conductive pads. The wiring structure includes a wiring structure upper surface and a wiring structure lower surface, the wiring structure upper surface facing the one surface of the semiconductor die stack, and the wiring structure lower surface opposite the wiring structure upper surface, and the wiring structure upper surface extends along a virtual plane. The conductive pads include a conductive pad surface facing one of the upper semiconductor die stack or the semiconductor die stack. The conductive pad surface is separated from the virtual plane in a direction perpendicular to the conductive pad surface.

Some example embodiments of the inventive concepts still further provide a semiconductor package that includes a semiconductor die stack stacked in a staircase shape; an encapsulation layer sealing the semiconductor die stack; a wiring structure facing one surface of the semiconductor die stack, the wiring structure including a plurality of conductive pads facing the semiconductor die stack; and a bonding wire connecting the semiconductor die stack to a conductive pad from among the plurality of conductive pads. The wiring structure includes a wiring structure upper surface and a wiring structure lower surface, the wiring structure upper surface facing the one surface of the semiconductor die stack, and the wiring structure lower surface opposite the wiring structure upper surface. The encapsulation layer includes a first encapsulation layer surface coplanar with another surface of the semiconductor die stack, the another surface of the semiconductor die stack being opposite the one surface of the semiconductor die stack; and a second encapsulation layer surface opposite the first encapsulation layer surface, the second encapsulation layer surface being in contact with the wiring structure upper surface. The conductive pad includes a conductive pad surface facing the second encapsulation layer surface. The plurality of conductive pads are grouped into a first conductive pad group and a second conductive pad group, first conductive pads of the first conductive pad group correspond to a semiconductor die from among the semiconductor die stack at a greatest distance away from the wiring structure upper surface. Each of second conductive pads of the second conductive pad group other than the first conductive pad group among the plurality of conductive pads includes a second conductive pad surface facing a bottom surface of the semiconductor die stack. Each of the first conductive pads includes a first conductive pad surface facing the bottom surface of the semiconductor die stack. The first conductive pad surface is separated from a virtual plane in a direction perpendicular to the first conductive pad surface.

### BRIEF DESCRIPTION OF THE DRAWINGS

Some example embodiments of the inventive concepts will be more clearly understood from the following detailed description taken in conjunction with the accompanying drawings in which:

FIG. 1 is a cross-sectional view of a semiconductor package according to some example embodiments;

FIG. 2 is a magnified view of a region CXL1 of FIG. 1;

FIG. 3 is a top view illustrating a state in which a first semiconductor die, a second semiconductor die, and a third semiconductor of FIG. 1 are stacked;

FIG. 4 is a cross-sectional view of a semiconductor package according to some example embodiments;

FIG. 5 is a magnified view of a region CXL2 of FIG. 4;

FIG. 6 is a cross-sectional view of a semiconductor package according to some example embodiments;

FIG. 7 is a magnified view of a region CXL3 of FIG. 6;

FIG. 8 is a cross-sectional view of a semiconductor package according to some example embodiments;

FIG. 9 is a magnified view of a region CXL4 of FIG. 8;

FIG. 10 is a cross-sectional view of a semiconductor package according to some example embodiments;

FIG. 11 is a magnified view of a region CXL5 of FIG. 10;

FIG. 12 is a cross-sectional view of a semiconductor package according to some example embodiments;

FIG. 13 is a magnified view of a region CXL6 of FIG. 12;

FIG. 14 is a cross-sectional view of a semiconductor package according to some example embodiments;

FIG. 15 is a cross-sectional view of a semiconductor package according to some example embodiments;

FIG. 16 is a cross-sectional view of a semiconductor package according to some example embodiments;

FIGS. 17, 18, 19, 20, 21, 22, 23 and 24 are cross-sectional views sequentially illustrating a process of manufacturing a semiconductor package, according to some example embodiments;

FIGS. 25, 26, 27 and 28 are cross-sectional views sequentially illustrating a process of manufacturing a semiconductor package, according to some example embodiments; and

FIGS. 29, 30, 31 and 32 are cross-sectional views sequentially illustrating a process of manufacturing a semiconductor package, according to some example embodiments.

### DETAILED DESCRIPTION

Hereinafter, some example embodiments are described in detail with reference to the accompanying drawings. Like reference numerals in the drawings denote like elements, and thus their repetitive description will be omitted.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

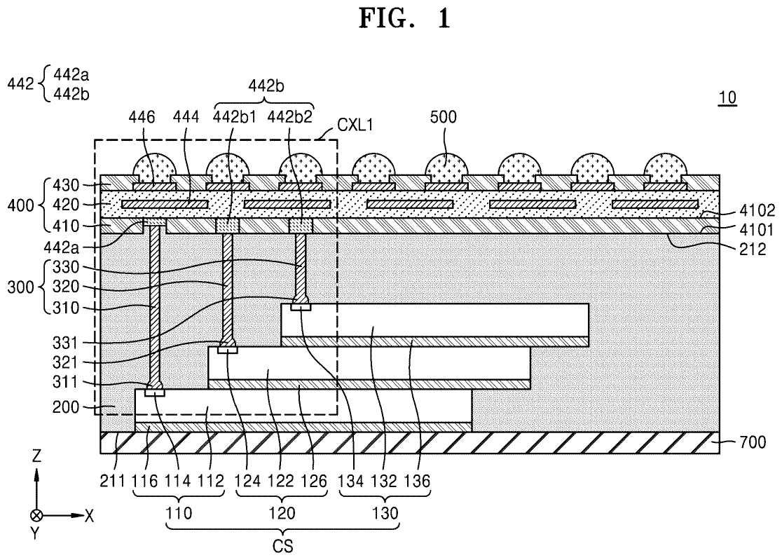

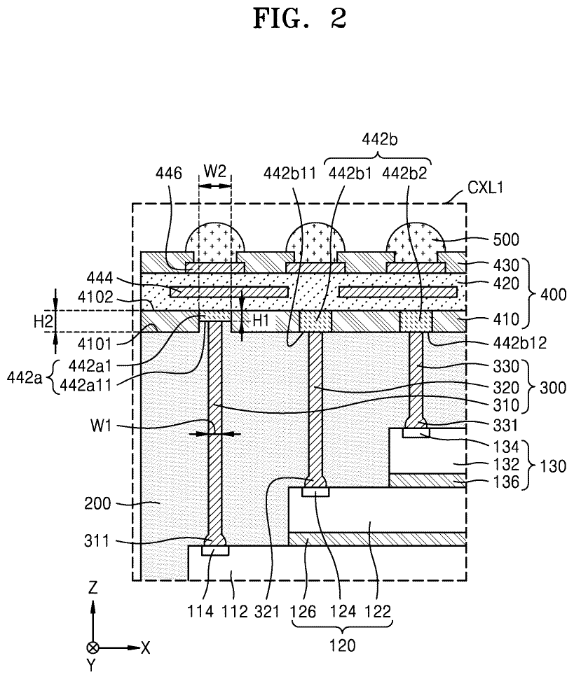

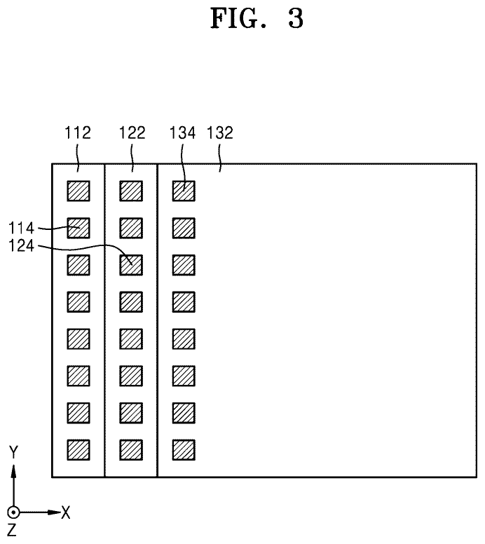

FIG. 1 is a cross-sectional view of a semiconductor package 10 according to some example embodiments, and FIG. 2 is a magnified view of a region CXL1 of FIG. 1. FIG. 3 is a top view illustrating a state in which a first semiconductor die, a second semiconductor die, and a third semiconductor of FIG. 1 are stacked.

Referring to FIGS. 1 to 3, the semiconductor package 10 according to an some example embodiments may include a semiconductor die stack CS, an encapsulation layer 200, a bonding wire group 300, a wiring structure 400, and an external connection terminal 500.

The semiconductor die stack CS may have a plurality of semiconductor dies, e.g., first to third semiconductor dies 110, 120, and 130, stacked in a staircase shape in a first horizontal direction (the X direction). The first horizontal direction (the X direction) may be a direction parallel to the surfaces of the first to third semiconductor dies 110, 120, and 130 and a first staircase creation direction in which the first to third semiconductor dies 110, 120, and 130 are stacked. The semiconductor die stack CS may include the first semiconductor die 110 at the bottom thereof, the second semiconductor die 120 on the first semiconductor die 110, and the third semiconductor die 130 on the second semiconductor die 120.

The first semiconductor die 110 may include a first body 112, a first die pad 114, and a first adhesive layer 116, the second semiconductor die 120 may include a second body 122, a second die pad 124, and a second adhesive layer 126, and the third semiconductor die 130 may include a third body 132, a third die pad 134, and a third adhesive layer 136.

According to some example embodiments, the semiconductor package 10 may further include a rear protective layer 700 attached to the lower surface of the first body 112 and a first surface 211 of the encapsulation layer 200. The rear protective layer 700 may protect the first semiconductor die 110 from an external physical impact. According to some example embodiments, the rear protective layer 700 may include a polymer-based material. The rear protective layer 700 may include a non-adhesive material, and in some example embodiments, the first adhesive layer 116 may attach the first body 112 to the rear protective layer 700. However, in some example embodiments, the rear protective layer 700 may include an adhesive material, because the first body 112 may be directly attached to the rear protective layer 700, the first adhesive layer 116 may not be between the rear protective layer 700 and the first body 112.

The first body 112, the second body 122, and the third body 132 are semiconductor substrates and may include a semiconductor material, e.g., a group IV semiconductor material, a group III-V semiconductor material, a group II-VI semiconductor material, or a combination thereof. The group IV semiconductor material may include, for example, silicon (Si), germanium (Ge), or a combination thereof. The group III-V semiconductor material may include, for example, gallium arsenide (GaAs), indium phosphide (InP), gallium phosphide (GaP), indium arsenide (InAs), indium antimonide (InSb), indium gallium arsenide (InGaAs), or a combination thereof. The group II-VI semiconductor material may include, for example, zinc telluride (ZnTe), cadmium sulfide (CdS), or a combination thereof. The semiconductor package 10 may be an arbitrary type of integrated circuit including a memory circuit, a logic circuit, or a combination thereof. The memory circuit may include, for example, a dynamic random access memory (DRAM) circuit, a static random access memory (SRAM) circuit, a flash memory circuit, an electrically erasable and programmable read-only memory (EEPROM) circuit, a phase-change random access memory (PRAM) circuit, a magnetic random access memory (MRAM) circuit, a resistive random access memory (RRAM) circuit, or a combination thereof. The logic circuit may include, for example, a central processing unit (CPU) circuit, a graphics processing unit (GPU) circuit, a controller circuit, an application specific integrated circuit (ASIC), an application processor (AP) circuit, or a combination thereof.

As shown in FIG. 3, first die pads 114 of the first semiconductor die 110 may be separated from each other in a second horizontal direction (the Y direction), second die pads 124 of the second semiconductor die 120 may be separated from each other in the second horizontal direction (the Y direction), and third die pads 134 of the third semiconductor die 130 may be separated from each other in the second horizontal direction (the Y direction). The second horizontal direction (the Y direction) may be a direction parallel to the surfaces of the first to third semiconductor dies 110, 120, and 130 and perpendicular to the first horizontal direction (the X direction) on the surfaces of the first to third semiconductor dies 110, 120, and 130. As described below, the first die pad 114 may be a terminal to which a first bonding wire 310 is connected, the second die pad 124 may be a terminal to which a second bonding wire 320 is connected, and the third die pad 134 may be a terminal to which a third bonding wire 330 is connected.

The first adhesive layer 116 of the first semiconductor die 110 may be attached along the lower surface of the first body 112. The first adhesive layer 116 may be between the rear protective layer 700 and the first body 112. The first adhesive layer 116 may include an insulating adhesive material, such as a die attach film (DAF). The thickness of the first adhesive layer 116 may be about tens of micrometers (μm).

The second adhesive layer 126 of the second semiconductor die 120 may be attached along the lower surface of the second body 122. The second adhesive layer 126 may be between the first semiconductor die 110 and the second semiconductor die 120. The second adhesive layer 126 may include an insulating adhesive material, such as a DAF. The thickness of the second adhesive layer 126 may be tens and about tens of μm.

The third adhesive layer 136 of the third semiconductor die 130 may be attached along the lower surface of the third body 132. The third adhesive layer 136 may be between the second semiconductor die 120 and the third semiconductor die 130. The third adhesive layer 136 may include an insulating adhesive material, such as a DAF. The thickness of the third adhesive layer 136 may be tens and about tens of μm.

According to some example embodiments, the encapsulation layer 200 may seal the semiconductor die stack CS. The encapsulation layer 200 may include the first surface 211 coplanar with the lower surface of the first semiconductor die 110 at the bottom of the semiconductor die stack CS and a second surface 212 that is opposite to the first surface 211. The height of the encapsulation layer 200 in the vertical direction (the Z direction) may be greater than the height of the semiconductor die stack CS in the vertical direction (the Z direction). In the specification, the vertical direction (the Z direction) may be defined as a direction in which the first to third semiconductor dies 110, 120, and 130 constituting the semiconductor die stack CS are stacked and a direction perpendicular to the first horizontal direction (the X direction) and the second horizontal direction (the Y direction).

According to some example embodiments, the top surface of the third semiconductor die 130 at the top of the semiconductor die stack CS may be separated from the second surface 212 of the encapsulation layer 200 in the vertical direction (the Z direction).

The encapsulation layer 200 may include, for example, a thermosetting resin, such as an epoxy resin, a thermoplastic resin, such as polyimide, or a resin an inorganic filler, for example, an Ajinomoto build-up film (ABF), a flame retardant class 4 (FR-4) resin, a bismaleimide triazine (BT) resin, or the like. The encapsulation layer 200 may for example include a molding material, such as an epoxy molding compound (EMC), or a photosensitive material, such as a photo imageable encapsulant (PIE).

The wiring structure 400 may be on the second surface 212 of the encapsulation layer 200. The wiring structure 400 may be a printed circuit board or a redistribution layer. The wiring structure 400 may include, for example, a first photosensitive resist layer 410, an insulating layer 420, a second photosensitive resist layer 430, a conductive pad 442 buried in the first photosensitive resist layer 410, a conductive pattern 444 buried in the insulating layer 420, and an external connection pad 446 buried in the second photosensitive resist layer 430.

The first photosensitive resist layer 410 may be disposed along the second surface 212 of the encapsulation layer 200. The lower surface of the first photosensitive resist layer 410 may be in contact with the second surface 212 of the encapsulation layer 200.

The conductive pad 442 may include a plurality of conductive pads 442a and 442b, and the plurality of conductive pads 442a and 442b may be buried in the first photosensitive resist layer 410 and exposed through the lower surface of the first photosensitive resist layer 410.

The plurality of conductive pads 442a and 442b may be grouped into, for example, a first conductive pad group 442a and a second conductive pad group 442b. A first conductive pad 442a1 belonging to the first conductive pad group 442a may correspond to the first semiconductor die 110 having the greatest distance to a wiring structure upper surface 4101 in the semiconductor die stack CS stacked in a staircase shape.

The first conductive pad 442a1 may have a first conductive pad surface 442a11 facing the semiconductor die stack CS. The first conductive pad surface 442a11 may be separated from a virtual plane including (e.g., extending from) the wiring structure upper surface 4101 in the direction perpendicular to the first conductive pad surface 442a11. For example, the first conductive pad surface 442a11 may not be included in the virtual plane. For example, the first conductive pad 442a1 may be stepped with respect to the wiring structure upper surface 4101. A thickness H1 of the first conductive pad 442a1 may be less than a thickness H2 of the first photosensitive resist layer 410. Herein, the wiring structure upper surface 4101 is coplanar with the lower surface of the first photosensitive resist layer 410.

The step of the first conductive pad 442a1 may be formed by reactive ion etching. The top of a metal layer may be etched due to an anisotropic etching reaction through reactive ion etching such that the thickness H1 of the first conductive pad 442a1 is less than the thickness H2 of the first photosensitive resist layer 410, thereby forming the step between the first conductive pad 442a1 and the wiring structure upper surface 4101. The anisotropic etching reaction may cause the first conductive pad surface 442a11 of the first conductive pad 442a1 to have a flat surface.

The first conductive pad 442a1 may be stepped with respect to the wiring structure upper surface 4101 to increase a contact strength with the first bonding wire 310. This is described below.

The second conductive pad group 442b may include second conductive pads 442b1 and 442b2 remaining by excluding the first conductive pad group 442a from the plurality of conductive pads 442a and 442b. The second conductive pads 442b1 and 442b2 belonging to the second conductive pad group 442b may include second conductive pad surfaces 442b11 and 442b12 facing the bottom surface of the semiconductor die stack CS, respectively. The second conductive pad surfaces 442b11 and 442b12 may be included in the virtual plane including the wiring structure upper surface 4101. For example, the second conductive pad surfaces 442b11 and 442b12 may be coplanar with the wiring structure upper surface 4101 and may not be stepped with respect to the wiring structure upper surface 4101.

The insulating layer 420 may be on the upper surface of the first photosensitive resist layer 410. The conductive pattern 444 may be buried in the insulating layer 420. The conductive pattern 444 may include a plurality of horizontal patterns extending in the first horizontal direction (the X direction) and/or the second horizontal direction (the Y direction) and having different vertical levels and vertical vias extending in the vertical direction (the Z direction) and connecting between the plurality of horizontal patterns having different vertical levels. For convenience of the drawings, horizontal patterns having different vertical levels and the vertical vias are not shown.

The second photosensitive resist layer 430 may be disposed along the upper surface of the insulating layer 420. The external connection pad 446 may be buried in the second photosensitive resist layer 430 and bonded with the external connection terminal 500. The external connection terminal 500 may include, for example, a conductive material including tin (Sn), lead (Pb), silver (Ag), copper (Cu), or a combination thereof. The external connection terminal 500 may be formed using, for example, a solder ball. The external connection terminal 500 may connect the semiconductor package 10 to a circuit board, another semiconductor package, an interposer, or a combination thereof.

The external connection terminal 500 may be bonded with the external connection pad 446. The external connection pad 446 may electrically and physically connect the external connection terminal 500 to the conductive pattern 444.

The first photosensitive resist layer 410 and the second photosensitive resist layer 430 may include, for example, a photo acid generator (PAG) and a photo base generator (PBG). The PAG has high light efficiency at which acid may be generated even with a low exposure dose. The PBG may generate base even with a high exposure dose because the PBG has lower light efficiency than the PAG.

The insulating layer 420 may include, for example, an inorganic insulating material, an organic insulating material, or a combination thereof. The inorganic insulating material may include, for example, Si oxide, Si nitride, or a combination thereof. The organic insulating material may include, for example, polyimide, an epoxy resin, or a combination thereof.

The conductive pattern 444, the plurality of conductive pads 442a and 442b, and the external connection pad 446 may include a conductive material including Cu, gold (Au), Ag, nickel (Ni), tungsten (W), aluminum (Al), or a combination thereof.

In some example embodiments, the conductive pattern 444, the plurality of conductive pads 442a and 442b, and the external connection pad 446 may further include a barrier material for limiting and/or preventing the conductive material from diffusing outward from the conductive pattern 444, the plurality of conductive pads 442a and 442b, and the external connection pad 446. The barrier material may include, for example, titanium (Ti), tantalum (Ta), titanium nitride (TiN), tantalum nitride (TaN), or a combination thereof.

The bonding wire group 300 may connect the first to third semiconductor dies 110, 120, and 130 to the wiring structure 400. The bonding wire group 300 may include first to third bonding wires 310, 320, and 330. A bonding wire may include a metal, such as Au, Ag, Cu, or platinum (Pt), which may be welded with a die pad by ultrasound energy and/or heat, or an alloy thereof. The bonding wire may have a length of hundreds and about hundreds of μm.

The bonding wire group 300 may include the first bonding wire 310, the second bonding wire 320, and the third bonding wire 330 connecting the first to third semiconductor dies 110, 120, and 130 to the wiring structure 400.

The first bonding wire 310 may have one end connected to the first die pad 114 of the first semiconductor die 110 and the other end electrically connected to the first conductive pad 442a1 of the wiring structure 400.

One end portion of the first bonding wire 310 may be a first protrusion portion 311. In a process of bonding the first bonding wire 310 with the first die pad 114 of the first semiconductor die 110, the first bonding wire 310 may be pressed to the first die pad 114. In some example embodiments, the one end portion of the first bonding wire 310 may be formed as the first protrusion portion 311 by physical and thermal pressure. The first protrusion portion 311 is integrated with the first bonding wire 310, and no interface is formed between the first protrusion portion 311 and the first bonding wire 310.

The other end portion of the first bonding wire 310 may be connected to the first conductive pad 442a1 of the wiring structure 400. The other end portion of the first bonding wire 310 may be in contact with the first conductive pad surface 442a11 of the first conductive pad 442a1. The other end portion of the first bonding wire 310 may be in contact with the first conductive pad surface 442a11, for example, vertically.

As described above, the thickness H1 of the first conductive pad 442a1 may be less than the thickness H2 of the first photosensitive resist layer 410 such that the first conductive pad 442a1 is stepped with respect to the first photosensitive resist layer 410. The first bonding wire 310 may be inserted into the step and bonded with the first conductive pad 442a1, thereby increasing the adhesive strength and/or reliability between the first bonding wire 310 and the first conductive pad 442a1.

For general vertical wire bonding, a bonding wire may be bent before the bonding wire reaches a conductive pad, or not be positioned at a center portion of the conductive pad. For example, as the length of a bonding wire increases, the possibility that the bonding wire is bent or not positioned at a center portion of a conductive pad increases. In the inventive concepts, by making the thickness H1 of the first conductive pad 442a1 less than the thickness H2 of the first photosensitive resist layer 410 to form the step between the first conductive pad 442a1 and the first photosensitive resist layer 410, the first bonding wire 310 to be vertically bonded with the first conductive pad 442a1 may be guided to the first conductive pad 442a1 by the step, thereby increasing an adhesive strength and/or reliability between the first bonding wire 310 and the first conductive pad 442a1.

The first to third bonding wires 310, 320, and 330 may be vertically bonded with the plurality of conductive pads 442a and 442b to reduce the length of a bonding wire compared to existing wire bonding, thereby increasing power efficiency and/or improving heat dissipation efficiency.

A diameter W1 of the first bonding wire 310 may be less than a diameter W2 of the first conductive pad 442a1. Accordingly, the first bonding wire 310 may be easily inserted by the step formed between the first conductive pad 442a1 and the first photosensitive resist layer 410.

One side of the second bonding wire 320 may be connected to the second die pad 124 of the second semiconductor die 120, and the other side of the second bonding wire 320 may be connected to the wiring structure 400. The second bonding wire 320 may linearly extend toward the second conductive pad 442b1. One end portion of the second bonding wire 320 may be a second protrusion portion 321 like the one end portion of the first bonding wire 310. Likewise, in a process of bonding the second bonding wire 320 with the second die pad 124 of the second semiconductor die 120, the second bonding wire 320 may be pressed to the second die pad 124. In some example embodiments, the one end portion of the second bonding wire 320 may be formed as the second protrusion portion 321 by physical and thermal pressure. The second protrusion portion 321 is integrated with the second bonding wire 320, and no interface is formed between the second protrusion portion 321 and the second bonding wire 320. The other side of the second bonding wire 320 may be in contact with a second conductive pad surface 442b11 of the second conductive pad 442b1.

One side of the third bonding wire 330 may be connected to the third die pad 134 of the third semiconductor die 130, and the other side of the third bonding wire 330 may be connected to the wiring structure 400. The third bonding wire 330 may linearly extend toward the second conductive pad 442b2. One end portion of the third bonding wire 330 may be a third protrusion portion 331 like the one end portion of the first bonding wire 310. Likewise, in a process of bonding the third bonding wire 330 with the third die pad 134 of the third semiconductor die 130, the third bonding wire 330 may be pressed to the third die pad 134. In some example embodiments, the one end portion of the third bonding wire 330 may be formed as the third protrusion portion 331 by physical and thermal pressure. The third protrusion portion 331 is integrated with the third bonding wire 330, and no interface is formed between the third protrusion portion 331 and the third bonding wire 330. The other side of the third bonding wire 330 may be in contact with a second conductive pad surface 442b12 of the second conductive pad 442b2.

The first bonding wire 310 may include a conductive material including Cu, Au, Ag, Ni, W, Al, or a combination thereof. In some example embodiments, the first bonding wire 310 may further include a barrier material for limiting and/or preventing the conductive material from diffusing outward from the first bonding wire 310. The barrier material may include, for example, Ti, Ta, TiN, TaN, or a combination thereof. Because a material included in the second bonding wire 320 and the third bonding wire 330 is also the same as a material included in the first bonding wire 310, a detailed description thereof is omitted herein.

The encapsulation layer 200 may be formed to mold both the bonding wire group 300 and the semiconductor die stack CS.

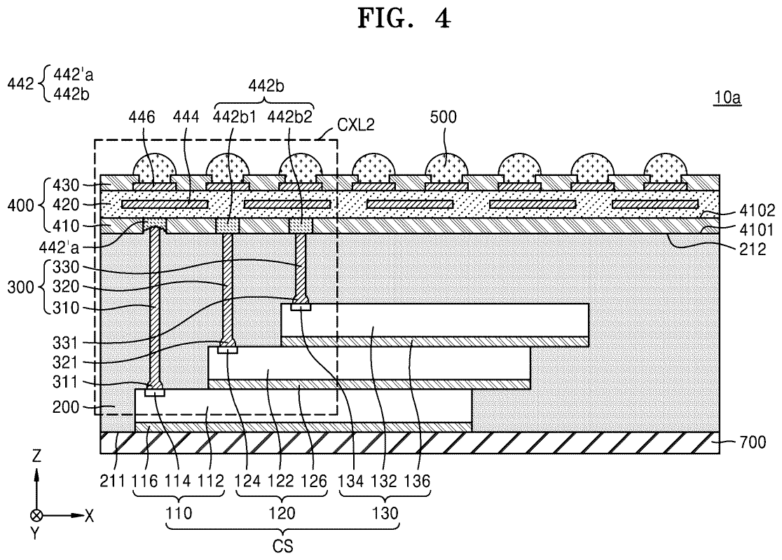

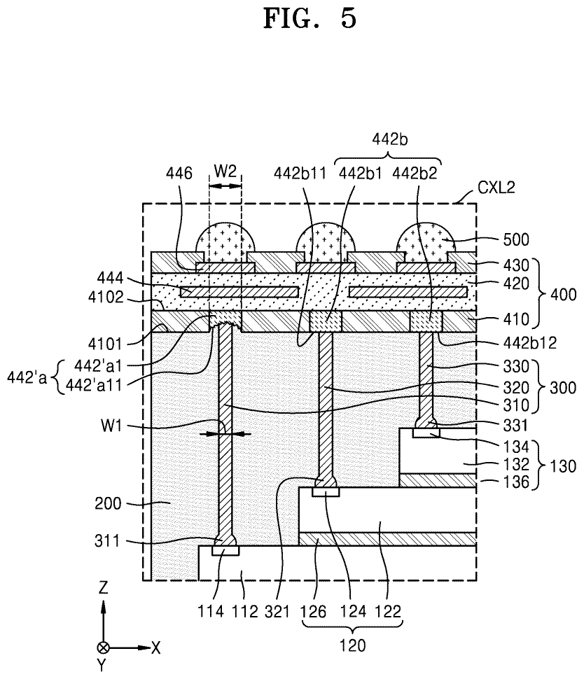

FIG. 4 is a cross-sectional view of a semiconductor package 10a according to some example embodiments, and FIG. 5 is a magnified view of a region CXL2 of FIG. 4. The semiconductor package 10a shown in FIGS. 4 and 5 may be almost the same as or similar to the semiconductor package 10 shown in FIGS. 1 to 3 except for a different shape of a first conductive pad group 442′a. Therefore, the description of elements made above with reference to FIGS. 1 to 3 is omitted or simply repeated.

Referring to FIGS. 4 and 5, the first conductive pad group 442′a has a different shape from that of the first conductive pad group 442a shown in FIG. 1. For example, while the first conductive pad 442a1 shown in FIG. 2 has a step with respect to the first photosensitive resist layer 410 and the first conductive pad surface 442a11 has a flat surface, a first conductive pad 442′a1 shown in FIG. 5 may have a shape recessed toward the semiconductor die stack CS. For example, the first conductive pad surface 442′a11 facing the semiconductor die stack CS may have a recessed shape. The thickness of a center portion of the first conductive pad 442′a1 may be less than the thickness of an edge portion thereof.

The first bonding wire 310 may be in contact with a recessed surface of the first conductive pad 442′a1 to increase the contact surface between the first bonding wire 310 and a first conductive pad surface 442′a11, thereby increasing the adhesive strength between the first bonding wire 310 and the first conductive pad 442′a1.

The first conductive pad surface 442′a11 of the first conductive pad 442′a1 may have roughness. Due to the roughness of the first conductive pad surface 442′a11, the contact area with the first bonding wire 310 may further increase, thereby further increasing the adhesive strength between the first bonding wire 310 and the first conductive pad 442′a1.

The recessed shape of the first conductive pad 442′a1 may be formed by plasma dry etching. A recess may be formed at the center of the top of a metal layer by plasma dry etching. According to the characteristic of plasma dry etching, roughness may be formed on the first conductive pad surface 442′a11 of the first conductive pad 442′a1.

The surface roughness of the conductive pad refers to fine irregularities formed to enhance adhesion strength with the bonding wire. The surface roughness may be measured by arithmetic mean roughness (Ra) and/or maximum roughness (Rmax). Here, the arithmetic mean roughness (Ra) refers to an average of absolute values of deviations from a center line over a measurement length on a roughness curve, and the maximum roughness (Rmax) refers to a vertical distance from a highest peak point to a lowest valley point on the roughness curve. The surface roughness may be measured using an atomic force microscope (AFM) or a surface roughness tester.

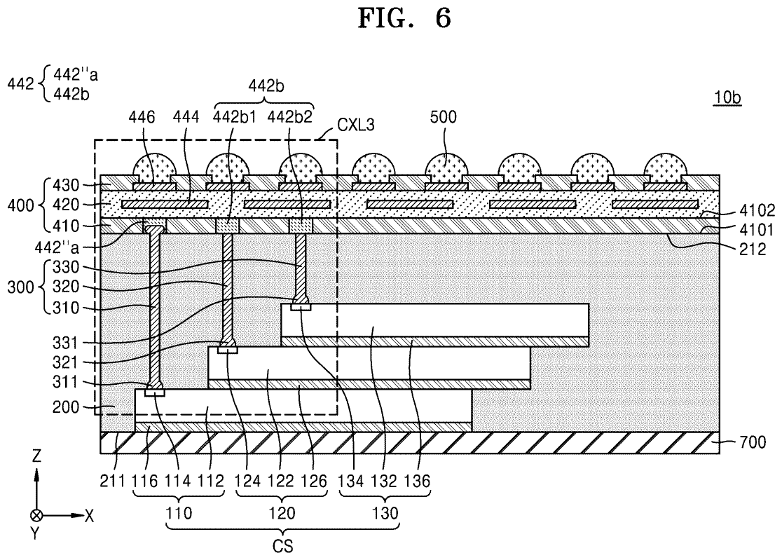

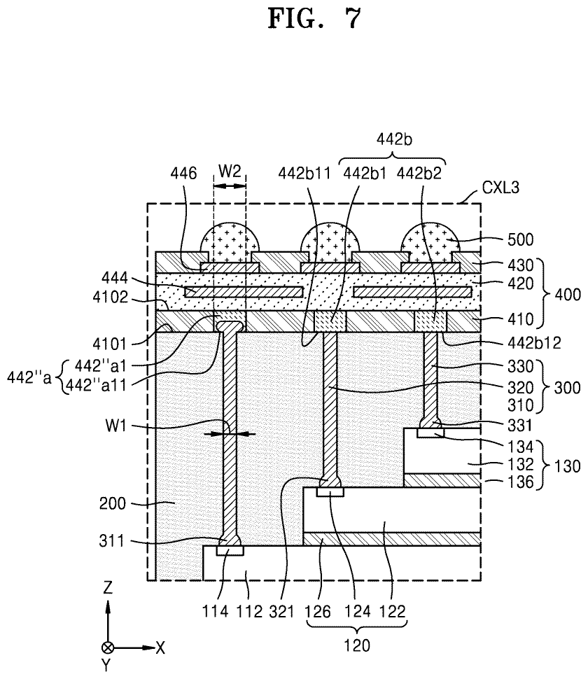

FIG. 6 is a cross-sectional view of a semiconductor package 10b according to some example embodiments, and FIG. 7 is a magnified view of a region CXL3 of FIG. 6. The semiconductor package 10b shown in FIGS. 6 and 7 may be almost the same as or similar to the semiconductor package 10 shown in FIGS. 1 to 3 except for a different shape of a first conductive pad group 442″a. Therefore, the description of elements made above with reference to FIGS. 1 to 3 is omitted or simply repeated.

Referring to FIGS. 6 and 7, the first conductive pad group 442″a has a different shape from that of the first conductive pad group 442a shown in FIG. 1. For example, while the first conductive pad 442a1 shown in FIG. 2 has a step with respect to the first photosensitive resist layer 410 and the first conductive pad surface 442a11 has a flat surface, a first conductive pad 442″a1 shown in FIG. 7 may have a shape of an undercut 442″a11.

The first bonding wire 310 may be positioned up to the inside of the undercut 442″a11 of the first conductive pad 442″a1. Accordingly, the contact surface between the first bonding wire 310 and the first conductive pad 442″a1 may increase, thereby increasing the adhesive strength between the first bonding wire 310 and the first conductive pad 442″a1.

The undercut 442″a11 of the first conductive pad 442″a1 may be formed by chemical wet etching. The undercut 442″a11 may be formed by etching a metal layer by an isotropic etching reaction through chemical wet etching.

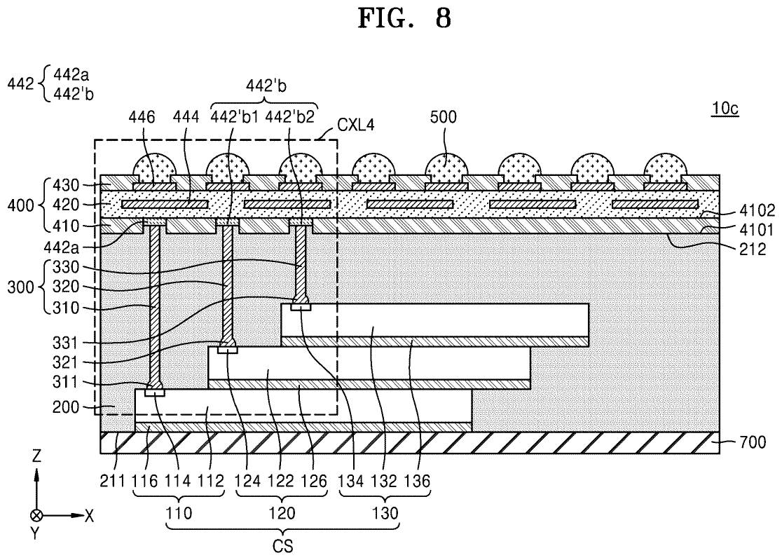

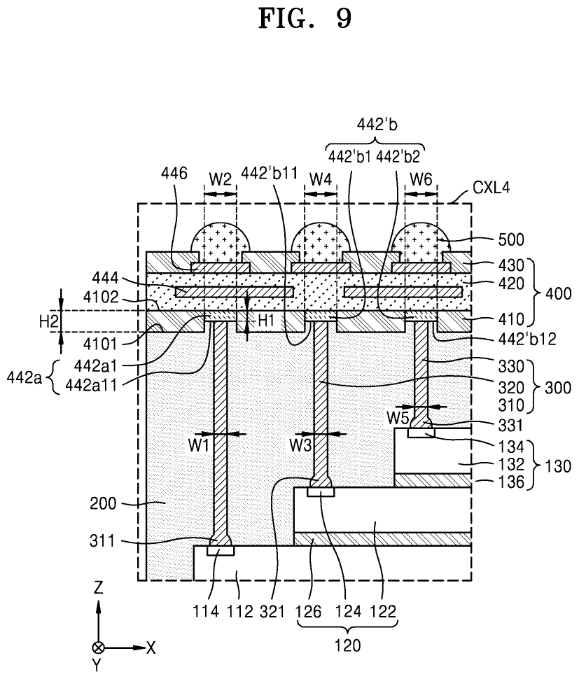

FIG. 8 is a cross-sectional view of a semiconductor package 10c according to some example embodiments, and FIG. 9 is a magnified view of a region CXL4 of FIG. 8. The semiconductor package 10c shown in FIGS. 8 and 9 may be almost the same as or similar to the semiconductor package 10 shown in FIGS. 1 to 3 except for a different shape of second conductive pads 442′b1 and 442′b2. Therefore, the description of elements made above with reference to FIGS. 1 to 3 is omitted or simply repeated.

Referring to FIGS. 8 and 9, the second conductive pads 442′b1 and 442′b2 belonging to a second conductive pad group 442′b differ in a shape from the second conductive pads 442b1 and 442b2 belonging to the second conductive pad group 442b shown in FIG. 1. For example, the second conductive pads 442b1 and 442b2 shown in FIG. 1 may include the second conductive pad surfaces 442b11 and 442b12 facing the bottom surface of the semiconductor die stack CS, respectively. The second conductive pad surfaces 442b11 and 442b12 may be included in the virtual plane including the wiring structure upper surface 4101. For example, the second conductive pad surfaces 442b11 and 442b12 may be coplanar with the wiring structure upper surface 4101 and may not be stepped with respect to the wiring structure upper surface 4101.

However, the second conductive pads 442′b1 and 442′b2 shown in FIGS. 8 and 9 may have second conductive pad surfaces 442′b11 and 442′b12 facing the semiconductor die stack CS, respectively. The second conductive pad surfaces 442′b11 and 442′b12 may be separated from the virtual plane including the wiring structure upper surface 4101 in the direction perpendicular to the second conductive pad surfaces 442′b11 and 442′b12. For example, the second conductive pad surfaces 442′b11 and 442′b12 may not be included in the virtual plane. For example, the second conductive pads 442′b1 and 442′b2 may be stepped with respect to the wiring structure upper surface 4101. The thickness H1 of the second conductive pads 442′b1 and 442′b2 may be less than the thickness H2 of the first photosensitive resist layer 410. Herein, the wiring structure upper surface 4101 is coplanar with the lower surface of the first photosensitive resist layer 410.

The second bonding wire 320 may be inserted into a step formed by the second conductive pad surface 442′b11 and the wiring structure upper surface 4101 and be in contact with the second conductive pad 442′b1, thereby increasing the adhesive strength and/or reliability between the second bonding wire 320 and the second conductive pad 442′b1.

The third bonding wire 330 may be inserted into a step formed by the second conductive pad surface 442′b12 and the wiring structure upper surface 4101 and be in contact with the second conductive pad 442′b2, thereby increasing the adhesive strength and/or reliability between the third bonding wire 330 and the second conductive pad 442′b2.

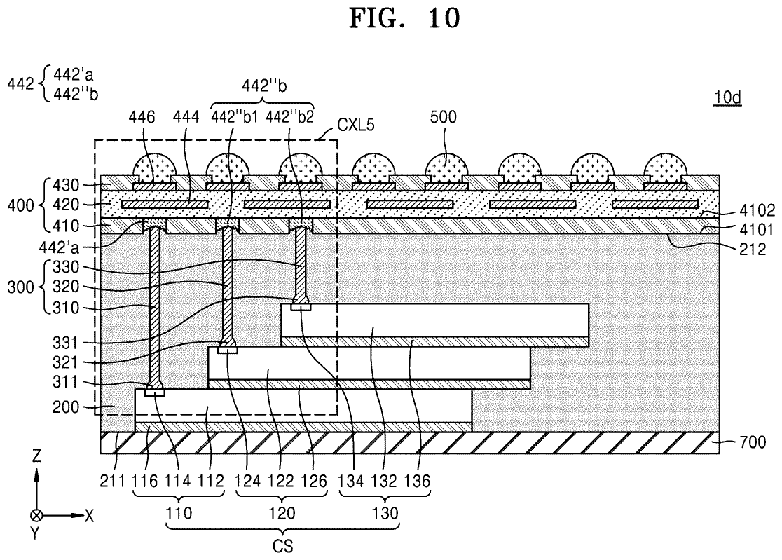

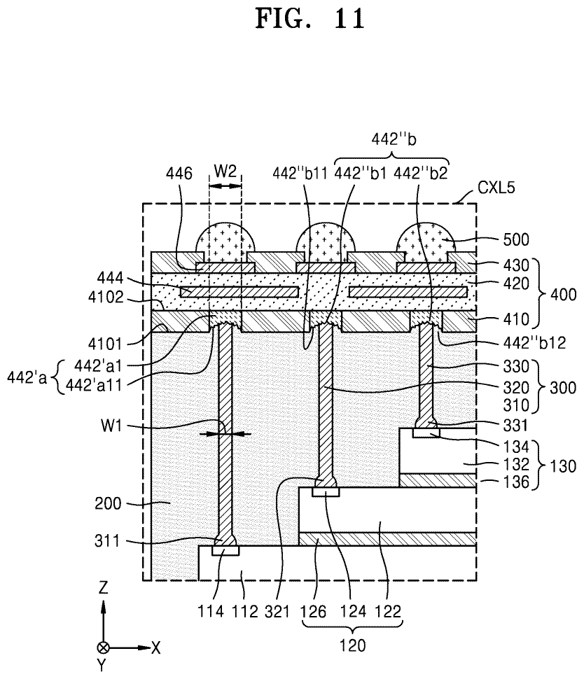

FIG. 10 is a cross-sectional view of a semiconductor package 10d according to some example embodiments, and FIG. 11 is a magnified view of a region CXL5 of FIG. 10. The semiconductor package 10d shown in FIGS. 10 and 11 may be almost the same as or similar to the semiconductor package 10 shown in FIGS. 1 to 3 except for different shapes of the first conductive pad group 442′a and second conductive pads 442″b1 and 442″b2. Therefore, the description of elements made above with reference to FIGS. 1 to 3 is omitted or simply repeated.

Referring to FIGS. 10 and 11, the second conductive pads 442″b1 and 442″b2 belonging to a second conductive pad group 442″b differ in a shape from the second conductive pads 442b1 and 442b2 belonging to the second conductive pad group 442b shown in FIG. 1. For example, the second conductive pads 442b1 and 442b2 shown in FIG. 1 may include the second conductive pad surfaces 442b11 and 442b12 facing the bottom surface of the semiconductor die stack CS, respectively. The second conductive pad surfaces 442b11 and 442b12 may be included in the virtual plane including the wiring structure upper surface 4101. For example, the second conductive pad surfaces 442b11 and 442b12 may be coplanar with the wiring structure upper surface 4101.

However, each of the second conductive pads 442″b1 and 442″b2 shown in FIGS. 10 and 11 may have a shape recessed toward the semiconductor die stack CS. For example, the second conductive pad surfaces 442″b11 and 442″b12 facing the semiconductor die stack CS may have a recessed shape. The thickness of a center portion of each of the second conductive pads 442″b1 and 442″b2 may be less than the thickness of an edge portion thereof.

The second bonding wire 320 may be in contact with a recessed surface of the second conductive pad 442″b1 to increase the contact surface between the second bonding wire 320 and a second conductive pad surface 442″b11, thereby increasing the adhesive strength and/or reliability between the second bonding wire 320 and the second conductive pad 442″b1.

The third bonding wire 330 may be in contact with a recessed surface of the second conductive pad 442″b2 to increase the contact surface between the third bonding wire 330 and a second conductive pad surface 442″b12, thereby increasing the adhesive strength and/or reliability between the third bonding wire 330 and the second conductive pad 442″b2.

The respective second conductive pad surfaces 442″b11 and 442″b12 of the second conductive pads 442″b1 and 442″b2 may have roughness. Due to the roughness of the second conductive pad surfaces 442″b11 and 442″b12, the contact area between the second bonding wire 320 and the third bonding wire 330 may further increase, thereby further increasing the adhesive strength and/or reliability between the second bonding wire 320 and the second conductive pad 442″b1 and further increasing the adhesive strength and/or reliability between the third bonding wire 330 and the second conductive pad 442″b2.

The recessed shape of the second conductive pads 442″b1 and 442″b2 may be formed by plasma dry etching. A recess may be formed at the center of the top of a metal layer by plasma dry etching. According to the characteristic of plasma dry etching, roughness may be formed on the respective second conductive pad surfaces 442″b11 and 442″b12 of the second conductive pads 442″b1 and 442″b2. Also, first conductive pad 442′a1 may have a recessed first conductive pad surface 442′a11 and roughness, as described with respect to FIGS. 4 and 5.

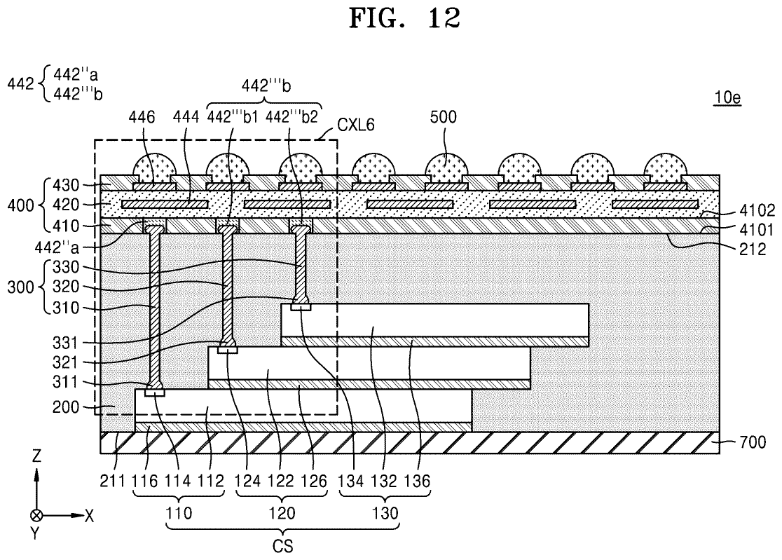

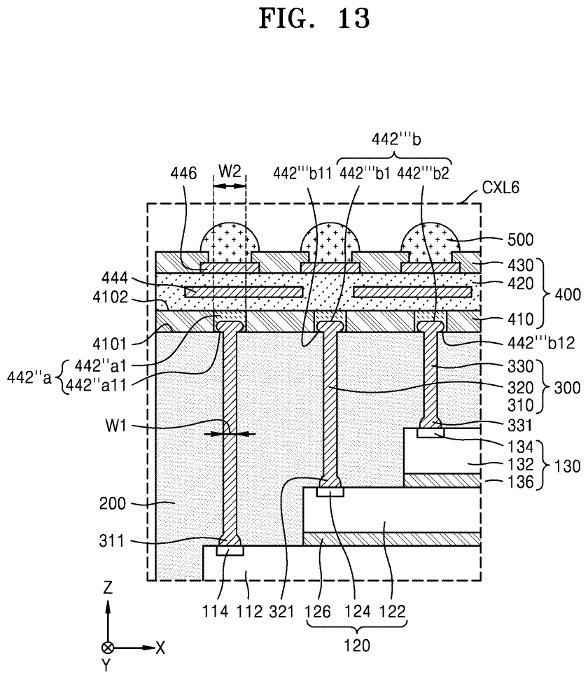

FIG. 12 is a cross-sectional view of a semiconductor package 10e according to some example embodiments, and FIG. 13 is a magnified view of a region CXL6 of FIG. 12. The semiconductor package 10e shown in FIGS. 12 and 13 may be almost the same as or similar to the semiconductor package 10 shown in FIGS. 1 to 3 except for different shapes of the first conductive pad group 442″a and second conductive pads 442′″b1 and 442′″b2. Therefore, the description of elements made above with reference to FIGS. 1 to 3 is omitted or simply repeated.

Referring to FIGS. 12 and 13, the second conductive pads 442″b1 and 442″b2 belonging to a third conductive pad group 442″b differ in a shape from the second conductive pads 442b1 and 442b2 belonging to the second conductive pad group 442b shown in FIG. 1. For example, the second conductive pads 442b1 and 442b2 shown in FIG. 1 may include the second conductive pad surfaces 442b11 and 442b12 facing the bottom surface of the semiconductor die stack CS, respectively. The second conductive pad surfaces 442b11 and 442b12 may be included in the virtual plane including the wiring structure upper surface 4101. For example, the second conductive pad surfaces 442b11 and 442b12 may be coplanar with the wiring structure upper surface 4101.

However, each of the second conductive pads 442′″b1 and 442″b2 shown in FIGS. 12 and 13 may have the shape of the undercut 442″a11 as described with respect to FIGS. 6 and 7.

The second bonding wire 320 may be positioned up to the inside of an undercut 442″b11 of the second conductive pad 442″b1. Accordingly, the contact surface between the second bonding wire 320 and the second conductive pad 442″b1 may increase, thereby increasing the adhesive strength and/or reliability between the second bonding wire 320 and the second conductive pad 442″b1.

The third bonding wire 330 may be positioned up to the inside of an undercut 442″b12 of the second conductive pad 442″b2. Accordingly, the contact surface between the third bonding wire 330 and the second conductive pad 442″b2 may increase, thereby increasing the adhesive strength and/or reliability between the third bonding wire 330 and the second conductive pad 442″b2.

The undercuts 442″b11 and 442″b12 of the second conductive pads 442′″b1 and 442″b2 may be formed by chemical wet etching. The undercuts 442″b11 and 442″b12 may be formed by etching a metal layer by an isotropic etching reaction through chemical wet etching. Also, first conductive pad 442″a1 may have the shape of the undercut 442″a11 described with respect to FIGS. 6 and 7.

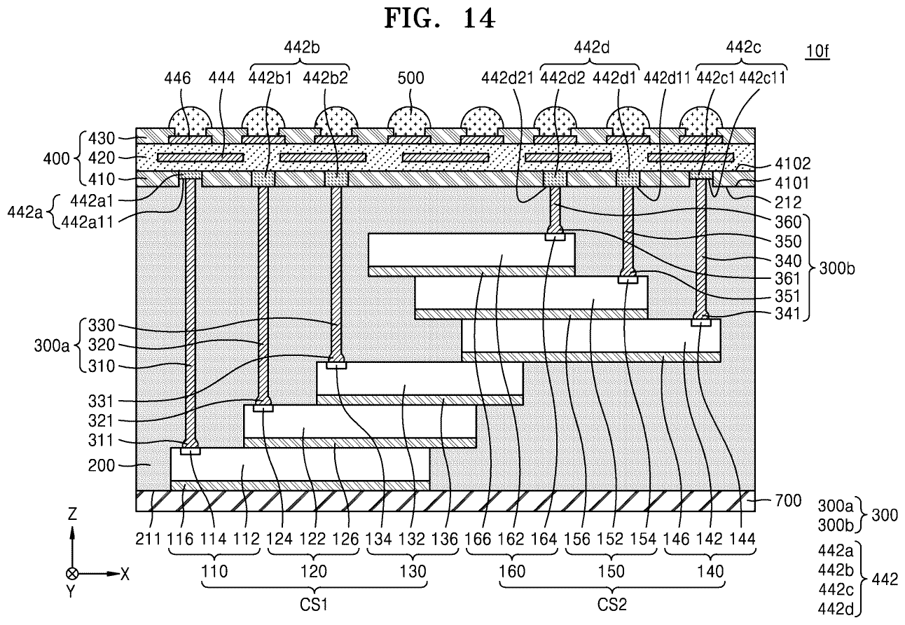

FIG. 14 is a cross-sectional view of a semiconductor package 10f according to some example embodiments. The semiconductor package 10f shown in FIG. 14 is almost the same as or similar to the semiconductor package 10 shown in FIGS. 1 to 3 except that the semiconductor package 10f further comprises an upper semiconductor die stack CS2, fourth to sixth bonding wires 340, 350, and 360, and third and fourth conductive pad groups 442c and 442d. Therefore, the description of elements made above with reference to FIGS. 1 to 3 is omitted or simply repeated.

The semiconductor package 10f shown in FIG. 14 differs from the semiconductor package 10 shown in FIG. 1 in that the semiconductor package 10f includes a lower semiconductor die stack CS1, the upper semiconductor die stack CS2, and the third and fourth conductive pad groups 442c and 442d electrically connected to the upper semiconductor die stack CS2. For example, the semiconductor package 10 shown in FIG. 1 may include the semiconductor die stack CS including a plurality of semiconductor dies, e.g., the first to third semiconductor dies 110, 120, and 130, stacked in a staircase shape in the first horizontal direction (the X direction).

However, the semiconductor package 10f shown in FIG. 14 may include the lower semiconductor die stack CS1 including a plurality of lower semiconductor dies, e.g., first to third lower semiconductor dies 110, 120, and 130, stacked in a staircase shape in the first horizontal direction (the X direction) and the upper semiconductor die stack CS2 including a plurality of upper semiconductor dies, e.g., first to third upper semiconductor dies 140, 150, and 160, stacked in a staircase shape in a first reverse horizontal direction (the −X direction) that is opposite to the first horizontal direction (the X direction).

The first reverse horizontal direction (the −X direction) may be a direction parallel to the surfaces of the first to third upper semiconductor dies 140, 150, and 160 and a second staircase creation direction in which the first to third upper semiconductor dies 140, 150, and 160 are stacked is opposite to the first staircase creation direction in which the first to third lower semiconductor dies 110, 120, and 130 are stacked. The upper semiconductor die stack CS2 may include the first upper semiconductor die 140 on the third lower semiconductor die 130, the second upper semiconductor die 150 on the first upper semiconductor die 140, and the third upper semiconductor die 160 on the second upper semiconductor die 150.

The first upper semiconductor die 140 may include a first upper body 142, a first upper die pad 144, and a fourth adhesive layer 146, the second upper semiconductor die 150 may include a second upper body 152, a second upper die pad 154, and a fifth adhesive layer 156, and the third upper semiconductor die 160 may include a third upper body 162, a third upper die pad 164, and a sixth adhesive layer 166.

The first lower body 112, the second lower body 122, and the third lower body 132 shown in FIG. 14 may have substantially the same configuration as the first body 112, the second body 122, and the third body 132 shown in FIG. 1, and the first upper body 142, the second upper body 152, and the third upper body 162 may be substantially the same as a first lower body 112, a second lower body 122, and a third lower body 132, respectively, and thus, a detailed description thereof is omitted herein.

The first upper die pad 144, the second upper die pad 154, and the third upper die pad 164 may be at one side of the upper surface of the first upper body 142, at one side of the upper surface of the second upper body 152, and at one side of the upper surface of the third upper body 162, respectively. The first upper die pad 144 may be a terminal to which a fourth bonding wire 340 is connected, the second upper die pad 154 may be a terminal to which a fifth bonding wire 350 is connected, and the third upper die pad 164 may be a terminal to which a sixth bonding wire 360 is connected.

The bonding wire group 300 may connect the first to third lower semiconductor dies 110, 120, and 130 and the first to third upper semiconductor dies 140, 150, and 160 to the wiring structure 400. The bonding wire group 300 may include a lower bonding wire group 300a connecting the first to third lower semiconductor dies 110, 120, and 130 to the wiring structure 400 and an upper bonding wire group 300b connecting the first to third upper semiconductor dies 140, 150, and 160 to the wiring structure 400.

The bonding wire group 300 may include a bonding wire. The bonding wire may include a metal, such as Au, Ag, Cu, or Pt, which may be welded with a die pad by ultrasound energy and/or heat, or an alloy thereof. The bonding wire may have a length of hundreds and about hundreds of μm.

The lower bonding wire group 300a may include the first bonding wire 310, the second bonding wire 320, and the third bonding wire 330 connecting a plurality of lower semiconductor dies, e.g., the first to third lower semiconductor dies 110, 120, and 130, selected from the lower semiconductor die stack CS1 to the wiring structure 400.

The lower bonding wire group 300a may connect the first lower semiconductor die 110, the second lower semiconductor die 120, and the third lower semiconductor die 130 to the wiring structure 400. The upper bonding wire group 300b may connect the first upper semiconductor die 140, the second upper semiconductor die 150, and the third upper semiconductor die 160 to the wiring structure 400.

The first bonding wire 310, the second bonding wire 320, and the third bonding wire 330 are the same as described above with reference to FIG. 1.

The fourth bonding wire 340 may have one end connected to the first upper die pad 144 of the first upper semiconductor die 140 and the other end electrically connected to a third conductive pad 442c1 of the wiring structure 400.

One end portion of the fourth bonding wire 340 may be a fourth protrusion portion 341. In a process of bonding the fourth bonding wire 340 with the first upper die pad 144 of the first upper semiconductor die 140, the fourth bonding wire 340 may be pressed to the first upper die pad 144. In some example embodiments, the one end portion of the fourth bonding wire 340 may be formed as the fourth protrusion portion 341 by physical and thermal pressure. The fourth protrusion portion 341 is integrated with the fourth bonding wire 340, and no interface is formed between the fourth protrusion portion 341 and the fourth bonding wire 340.

The other end portion of the fourth bonding wire 340 may be connected to the third conductive pad 442c1 of the wiring structure 400. The other end portion of the fourth bonding wire 340 may be in contact with a third conductive pad surface 442c11 of the third conductive pad 442c 1. The other end portion of the fourth bonding wire 340 may be in contact with the third conductive pad surface 442c11, for example, vertically.

Like the first conductive pad 442a1, the thickness of the third conductive pad 442c1 may be less than the thickness of the first photosensitive resist layer 410 such that the third conductive pad 442c1 is stepped with respect to the first photosensitive resist layer 410. The fourth bonding wire 340 may be inserted into the step and bonded with the third conductive pad 442c1, thereby increasing the adhesive strength and/or reliability between the fourth bonding wire 340 and the third conductive pad 442c1.

One side of the fifth bonding wire 350 may be connected to the second upper die pad 154 of the second upper semiconductor die 150, and the other side of the fifth bonding wire 350 may be connected to the wiring structure 400. The fifth bonding wire 350 may linearly extend toward a fourth conductive pad 442d1. One end portion of the fifth bonding wire 350 may be a fifth protrusion portion 351. In a process of bonding the fifth bonding wire 350 with the second upper die pad 154 of the second upper semiconductor die 150, the fifth bonding wire 350 may be pressed to the second upper die pad 154. In some example embodiments, the one end portion of the fifth bonding wire 350 may be formed as the fifth protrusion portion 351 by physical and thermal pressure. The fifth protrusion portion 351 is integrated with the fifth bonding wire 350, and no interface is formed between the fifth protrusion portion 351 and the fifth bonding wire 350. The other side of the fifth bonding wire 350 may be in contact with a fourth conductive pad surface 442d11 of the fourth conductive pad 442d1.

One side of the sixth bonding wire 360 may be connected to the third upper die pad 164 of the third upper semiconductor die 160, and the other side of the sixth bonding wire 360 may be connected to the wiring structure 400. The sixth bonding wire 360 may linearly extend toward a fourth conductive pad 442d2. One end portion of the sixth bonding wire 360 may be a sixth protrusion portion 361. In a process of bonding the sixth bonding wire 360 with the third upper die pad 164 of the third upper semiconductor die 160, the sixth bonding wire 360 may be pressed to the third upper die pad 164. In some example embodiments, the one end portion of the sixth bonding wire 360 may be formed as the sixth protrusion portion 361 by physical and thermal pressure. The sixth protrusion portion 361 is integrated with the sixth bonding wire 360, and no interface is formed between the sixth protrusion portion 361 and the sixth bonding wire 360. The other side of the sixth bonding wire 360 may be in contact with a fourth conductive pad surface 442d21 of the fourth conductive pad 442d2.

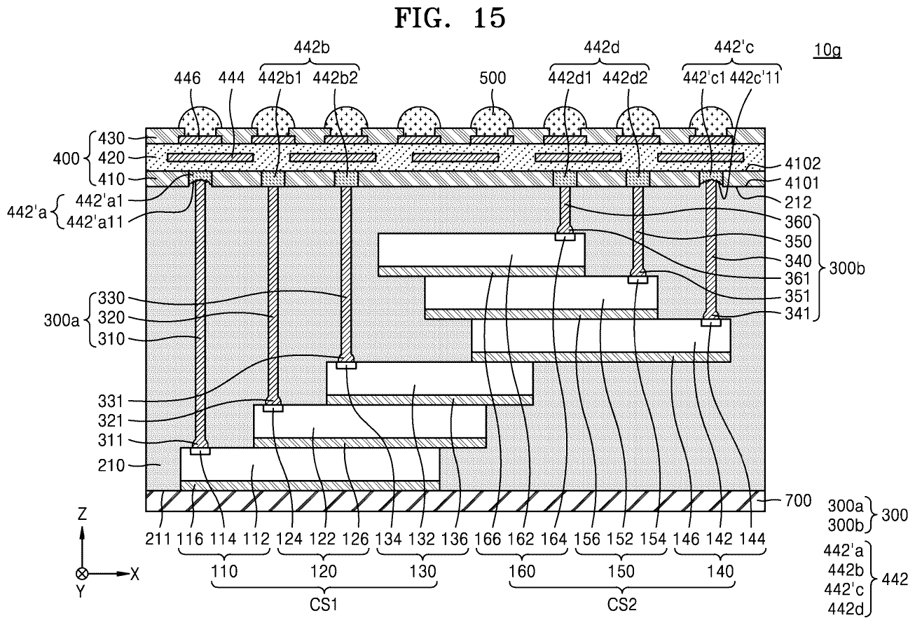

FIG. 15 is a cross-sectional view of a semiconductor package 10g according to some example embodiments. The semiconductor package 10g shown in FIG. 15 may be almost the same as or similar to the semiconductor package 10f shown in FIG. 14 except for a different shape of the first conductive pad 442′a1 and a different shape of a third conductive pad 442′c1. The first conductive pad 442′a1 of the semiconductor package 10g shown in FIG. 15 is the same as the first conductive pad 442′a1 of the semiconductor package 10a shown in FIGS. 4 and 5. Therefore, the description of elements made above with reference to FIGS. 1 to 5 and 14 is omitted or simply repeated.

Referring to FIG. 15, the third conductive pad group 442′c differs from the third conductive pad group 442c shown in FIG. 14 in a shape. For example, while the third conductive pad 442c1 shown in FIG. 14 has a step with respect to the first photosensitive resist layer 410 and the third conductive pad surface 442c11 has a flat surface, a third conductive pad 442′c1 shown in FIG. 15 may have a shape recessed toward the upper semiconductor die stack CS2. For example, the third conductive pad surface 442′c11 facing the upper semiconductor die stack CS2 may have a recessed shape. The thickness of a center portion of the third conductive pad 442′c1 may be less than the thickness of an edge portion thereof.

The fourth bonding wire 340 may be in contact with a recessed surface of the third conductive pad 442′c1 to increase the contact surface between the fourth bonding wire 340 and a third conductive pad surface 442′c11, thereby increasing the adhesive strength and/or reliability between the fourth bonding wire 340 and the third conductive pad 442′c1.

The third conductive pad surface 442′c11 of the third conductive pad 442′c1 may have roughness. Due to the roughness of the third conductive pad surface 442′c11, the contact area with the fourth bonding wire 340 may further increase, thereby further increasing the adhesive strength and/or reliability between the fourth bonding wire 340 and the third conductive pad 442′c1.

The recessed shape of the third conductive pad 442′c1 may be formed by plasma dry etching. A recess may be formed at the center of the top of a metal layer by plasma dry etching. According to the characteristic of plasma dry etching, roughness may be formed on the third conductive pad surface 442′c11 of the third conductive pad 442′c1.

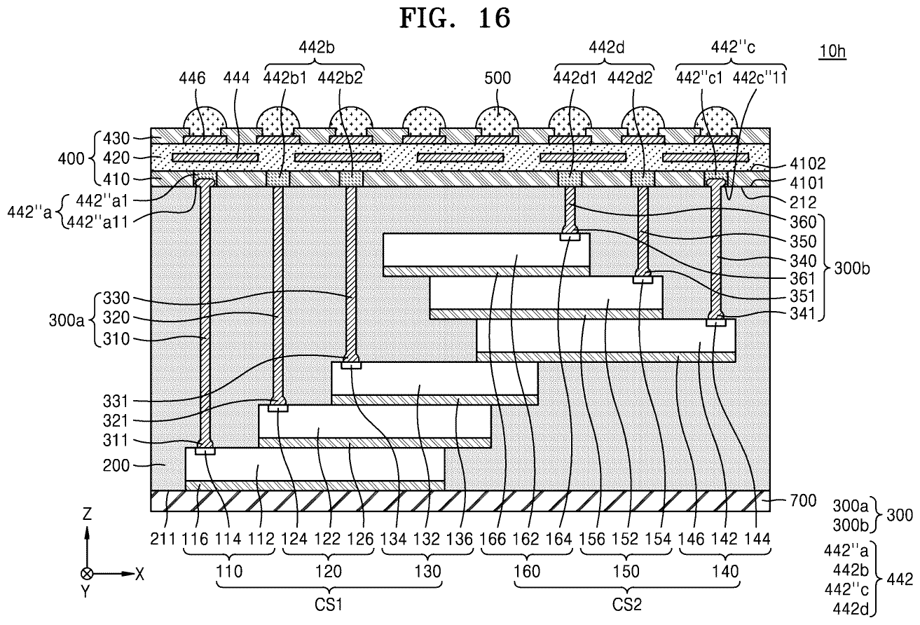

FIG. 16 is a cross-sectional view of a semiconductor package 10h according to some example embodiments. The semiconductor package 10h shown in FIG. 16 may be almost the same as or similar to the semiconductor package 10f shown in FIG. 14 except for a different shape of the first conductive pad 442″a1 and a different shape of a third conductive pad 442″c1. The first conductive pad 442″a1 of the semiconductor package 10h shown in FIG. 16 is the same as the first conductive pad 442″a1 of the semiconductor package 10b shown in FIGS. 6 and 7. Therefore, the description of elements made above with reference to FIGS. 1 to 7 and 15 is omitted or simply repeated.

Referring to FIG. 16, the third conductive pad 442″c1 differs from the third conductive pad 442c1 shown in FIG. 14 in a shape. For example while the third conductive pad 442c1 shown in FIG. 14 has a step with respect to the first photosensitive resist layer 410 and the third conductive pad surface 442c11 has a flat surface, a third conductive pad 442″c1 shown in FIG. 16 may have a shape of an undercut 442″c11.

The fourth bonding wire 340 may be positioned up to the inside of the undercut 442″c11 of the third conductive pad 442″c1. Accordingly, the contact surface between the fourth bonding wire 340 and the third conductive pad 442″c1 may increase, thereby increasing the adhesive strength and/or reliability between the fourth bonding wire 340 and the third conductive pad 442″c1.

The undercut 442″c11 of the third conductive pad 442″c1 may be formed by chemical wet etching. The undercut 442″c11 may be formed by etching a metal layer by an isotropic etching reaction through chemical wet etching.

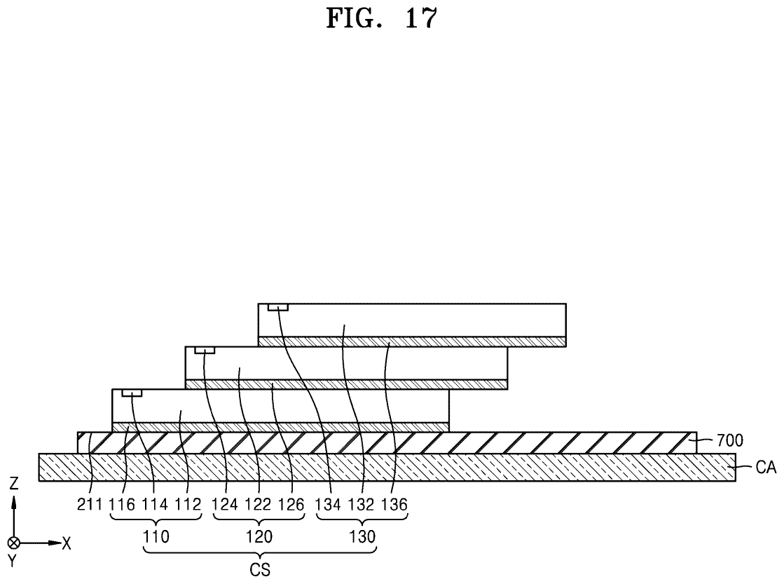

FIGS. 17 to 24 are cross-sectional views sequentially illustrating a process of manufacturing a semiconductor package, according to some example embodiments. The semiconductor package is the semiconductor package 10 described with reference to FIGS. 1 to 3.

For example, the description made with reference to FIGS. 1 to 3 is simply repeated or omitted with reference to FIGS. 17 to 24. Referring to FIG. 17, the semiconductor die stack CS may be formed on a carrier substrate CA. The carrier substrate CA may be a glass carrier substrate, a silicon carrier substrate, a ceramic carrier substrate, or the like. Alternatively, the carrier substrate CA may be a wafer.

The semiconductor die stack CS may include the first semiconductor die 110 in contact with the carrier substrate CA.

A plurality of semiconductor dies, e.g., the first to third semiconductor dies 110, 120, and 130, may be stacked on the carrier substrate CA in a staircase shape in the first horizontal direction (the X direction) to form the semiconductor die stack CS. The first horizontal direction (the X direction) may be a direction parallel to the surfaces of the first to third semiconductor dies 110, 120, and 130 and the first staircase creation direction in which the first to third semiconductor dies 110, 120, and 130 are stacked.

The first semiconductor die 110 may include the first body 112, the first die pad 114 at an edge side of the upper surface of the first body 112 and exposed on the upper surface of the first body 112, and the first adhesive layer 116 between the rear protective layer 700 and the first body 112.

The second semiconductor die 120 may include the second body 122, the second die pad 124 at an edge side of the upper surface of the second body 122 and exposed on the upper surface of the second body 122, and the second adhesive layer 126 between the first body 112 and the second body 122.

The third semiconductor die 130 may include the third body 132, the third die pad 134 at an edge side of the upper surface of the third body 132 and exposed on the upper surface of the third body 132, and the third adhesive layer 136 between the second body 122 and the third body 132.

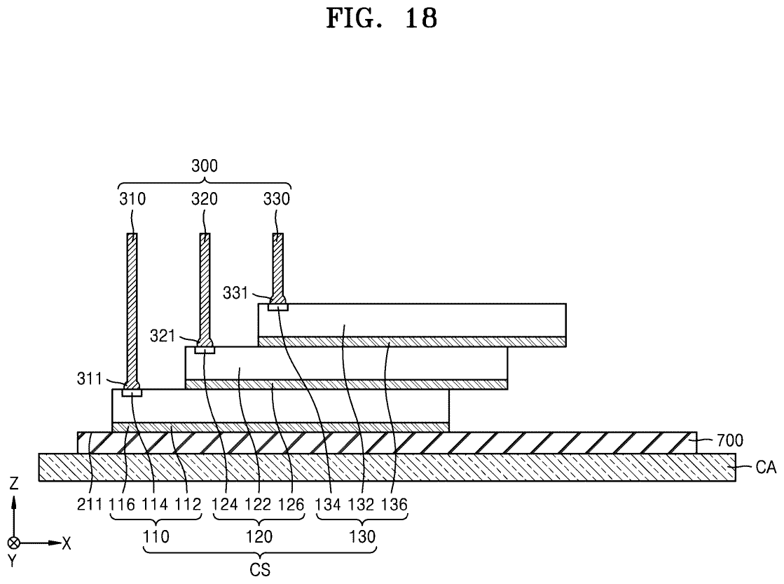

Referring to FIG. 18, the first bonding wire 310, the second bonding wire 320, and the third bonding wire 330 connected to the semiconductor die stack CS may be formed. The first bonding wire 310 may be bonded with the first die pad 114 of the first semiconductor die 110, the second bonding wire 320 may be bonded with the second die pad 124 of the second semiconductor die 120, and the third bonding wire 330 may be bonded with the third die pad 134 of the third semiconductor die 130.

In a process of bonding the first bonding wire 310 with the first semiconductor die 110, the first bonding wire 310 may be pressed to the first die pad 114, and in some example embodiments, the first protrusion portion 311 may be formed at one end of the first bonding wire 310 by thermocompression and physical compression.

The second bonding wire 320 may adhere to the second die pad 124 and extend in the vertical direction (the Z direction). In a process of bonding the second bonding wire 320 with the second semiconductor die 120, the second bonding wire 320 may be pressed to the second die pad 124, and in some example embodiments, the second protrusion portion 321 may be formed at one end of the second bonding wire 320 by thermocompression and physical compression.

The third bonding wire 330 may adhere to the third die pad 134 and extend in the vertical direction (the Z direction). In a process of bonding the third bonding wire 330 with the third semiconductor die 130, the third bonding wire 330 may be pressed to the third die pad 134, and in some example embodiments, the third protrusion portion 331 may be formed at one end of the third bonding wire 330 by thermocompression and physical compression.

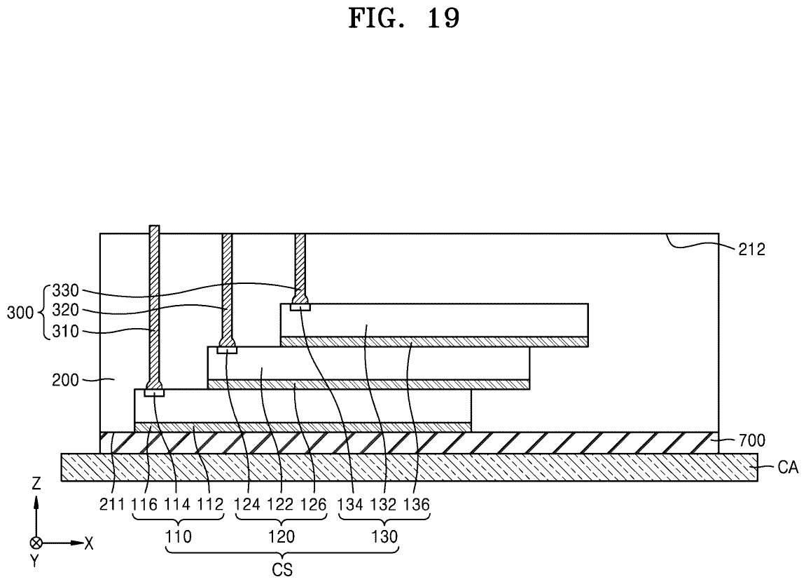

Referring to FIG. 19, a molding material is filled to mold the semiconductor die stack CS and the first to third bonding wires 310, 320, and 330 on the carrier substrate CA, thereby forming the encapsulation layer 200.

Thereafter, portions of the second bonding wire 320 and the third bonding wire 330 and a portion of the top of the encapsulation layer 200 may be polished. In the polishing, the other end of the first bonding wire 310 may not be polished, and after the polishing, the other end of the first bonding wire 310 may be exposed upward from the top of the encapsulation layer 200.

After the polishing, the carrier substrate CA may be removed. However, according to a manufacturing process of some example embodiments, the carrier substrate CA may not be removed, and a post-process may be performed with the carrier substrate CA attached to the bottom surface of the encapsulation layer 200.

After etching the top of the encapsulation layer 200, the second bonding wire 320 and the third bonding wire 330 may be exposed on (e.g., at) the second surface 212 of the encapsulation layer 200. A portion of the first bonding wire 310 may protrude upward from the second surface 212 of the encapsulation layer 200.

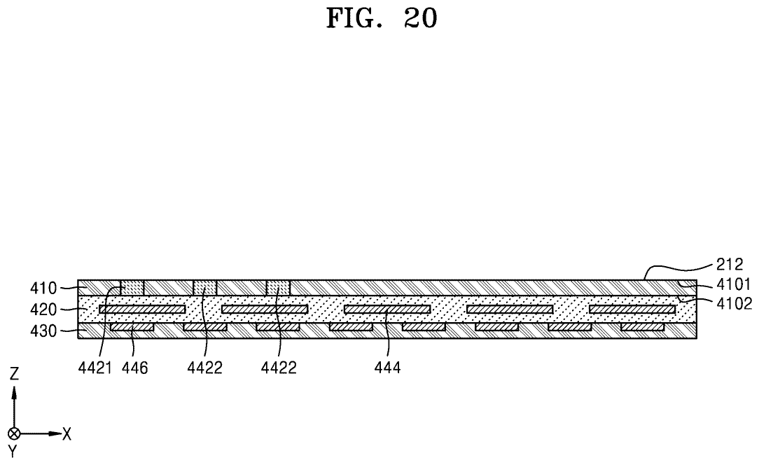

FIGS. 20 to 23 are cross-sectional views sequentially illustrating a process of manufacturing the wiring structure 400 according to some example embodiments.

Referring to FIG. 20, a wiring structure may be prepared. The wiring structure may include the first photosensitive resist layer 410, the insulating layer 420, the second photosensitive resist layer 430, metal patterns 4421 and 4422 buried in the first photosensitive resist layer 410, the conductive pattern 444 buried in the insulating layer 420, and the external connection pad 446 buried in the second photosensitive resist layer 430.

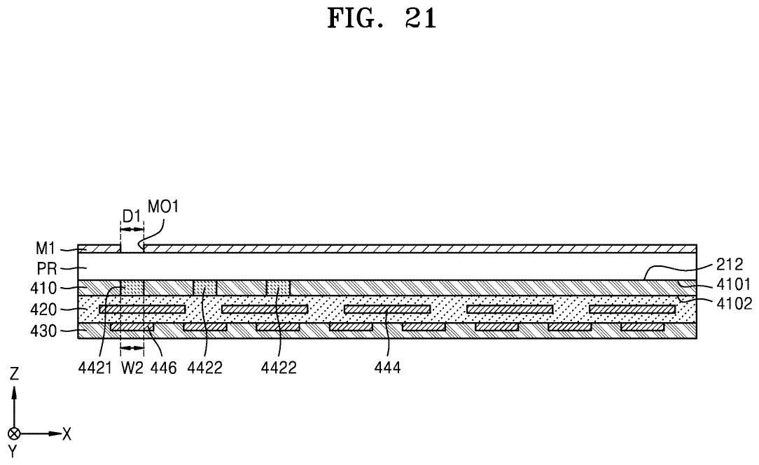

Referring to FIG. 21, a photoresist PR may be formed on the first photosensitive resist layer 410. A mask M1 may be provided on the photoresist PR. An opening MO1 of the mask M1 may have a diameter D1 that is the same or substantially the same as the diameter W2 of the metal pattern 4421.

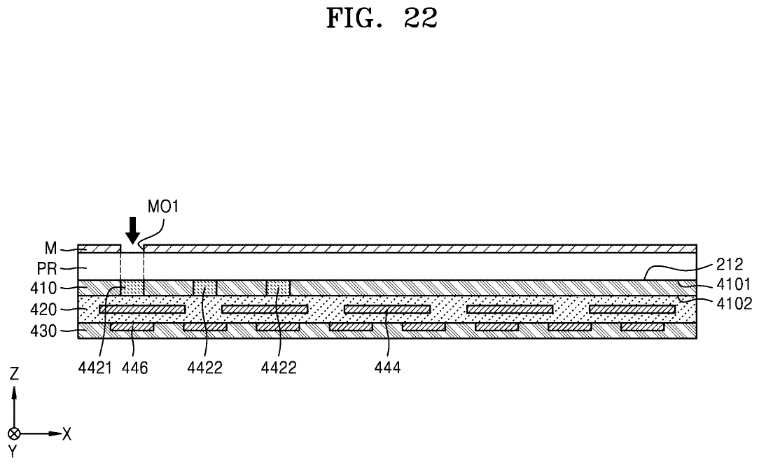

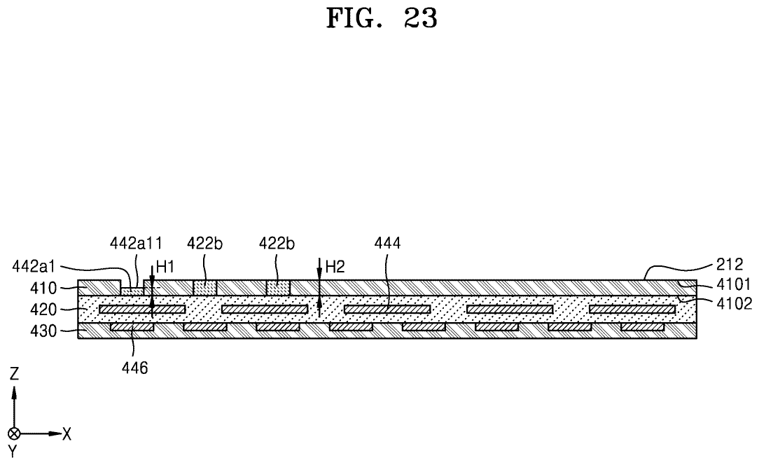

Referring to FIGS. 22 and 23, reactive ion etching may be performed. The top of a metal layer may be etched due to an anisotropic etching reaction through reactive ion etching such that the thickness H1 of the first conductive pad 442a1 is less than the thickness H2 of the first photosensitive resist layer 410, thereby forming a step between the first conductive pad 442a1 and the wiring structure upper surface 4101. The anisotropic etching reaction may cause the first conductive pad surface 442a11 of the first conductive pad 442a1 to have a flat surface.

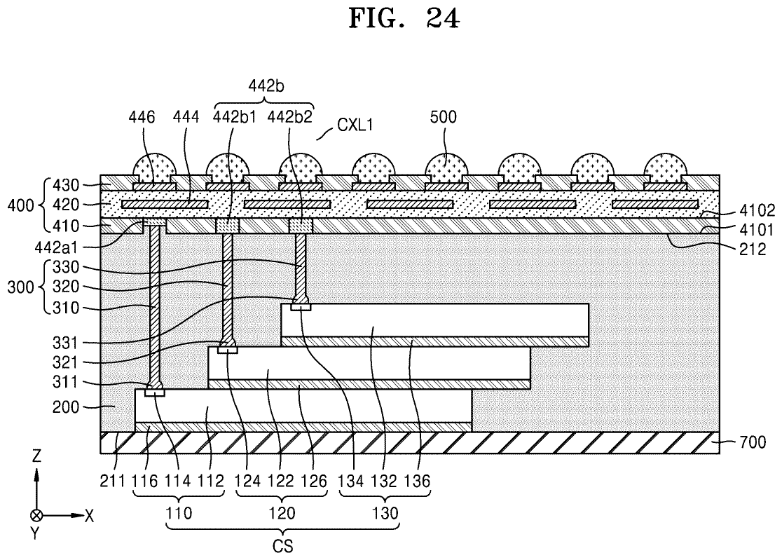

Referring to FIG. 24, after manufacturing the wiring structure 400, the wiring structure 400 may be attached onto the second surface 212 of the encapsulation layer 200 shown in FIG. 19.

When the wiring structure 400 is attached onto the second surface 212 of the encapsulation layer 200, the first and second conductive pads 442a1, 442b1, and 442b2 of the wiring structure 400 may be aligned with the first to third bonding wires 310, 320, and 330, the other end of the first bonding wire 310 may be in contact with the first conductive pad 442a1, the other end of the second bonding wire 320 may be in contact with the second conductive pad 442b1, and the other end of the third bonding wire 330 may be in contact with the second conductive pad 442b2.

Thereafter, the external connection terminal 500 may be attached onto the external connection pad 446 exposed on the second photosensitive resist layer 430 of the wiring structure 400. The external connection terminal 500 may be, for example, a solder ball or a bump. When the external connection terminal 500 is attached thereto, the semiconductor package 10 as shown in FIG. 24 may be completed.

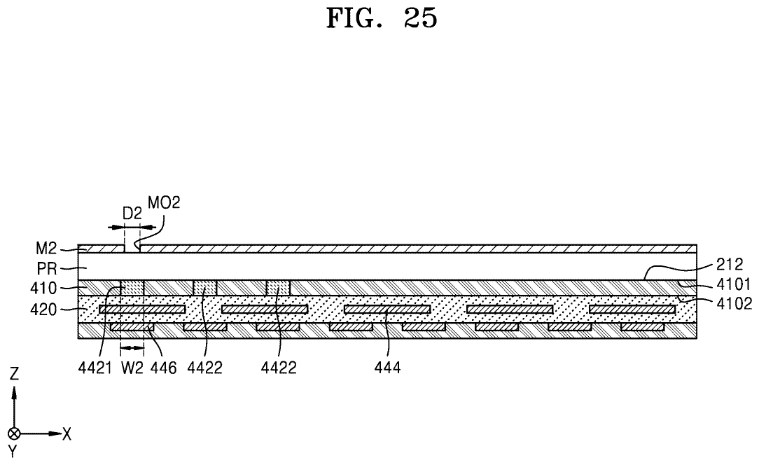

FIGS. 25 to 28 are cross-sectional views sequentially illustrating a process of manufacturing a semiconductor package, according to some example embodiments.

FIG. 25 is a cross-sectional view corresponding to FIG. 21. Therefore, the description made above with reference to FIGS. 20 to 23 is omitted herein.

Referring to FIG. 25, the photoresist PR may be formed on the first photosensitive resist layer 410. A mask M2 may be provided on the photoresist PR. An opening MO2 of the mask M2 may have a diameter D2 that is less than the diameter W2 of the metal pattern 4421.

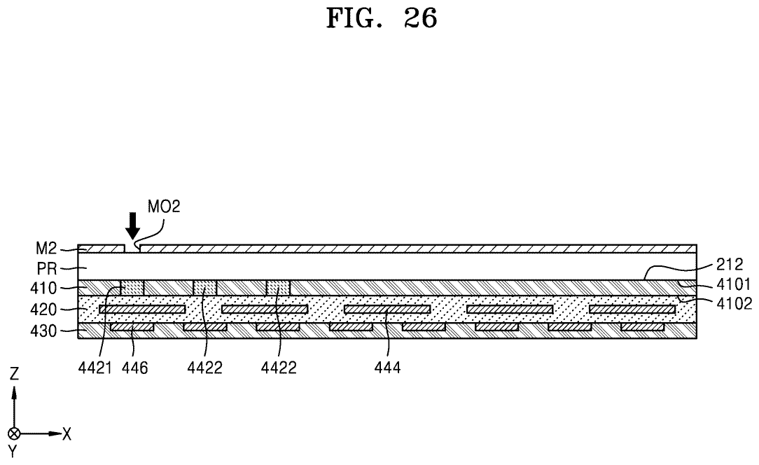

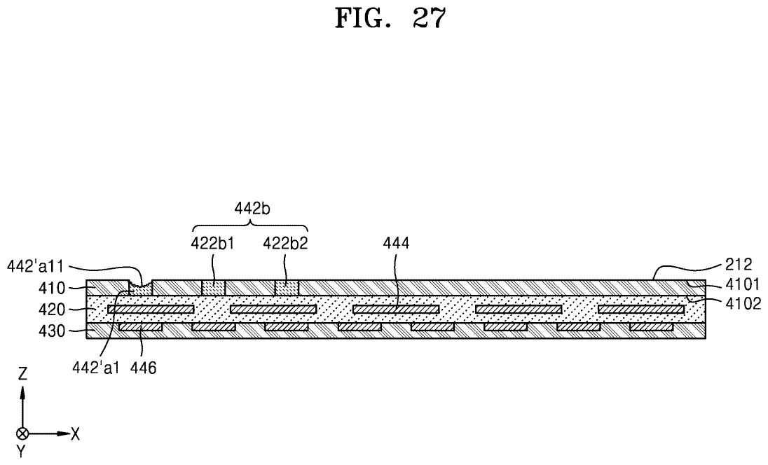

Referring to FIGS. 26 and 27, plasma dry etching may be performed. A recess may be formed at the center of the top of the metal pattern 4421 by plasma dry etching. According to the characteristic of plasma dry etching, roughness may be formed on the first conductive pad surface 442′a11 of the first conductive pad 442′a1.

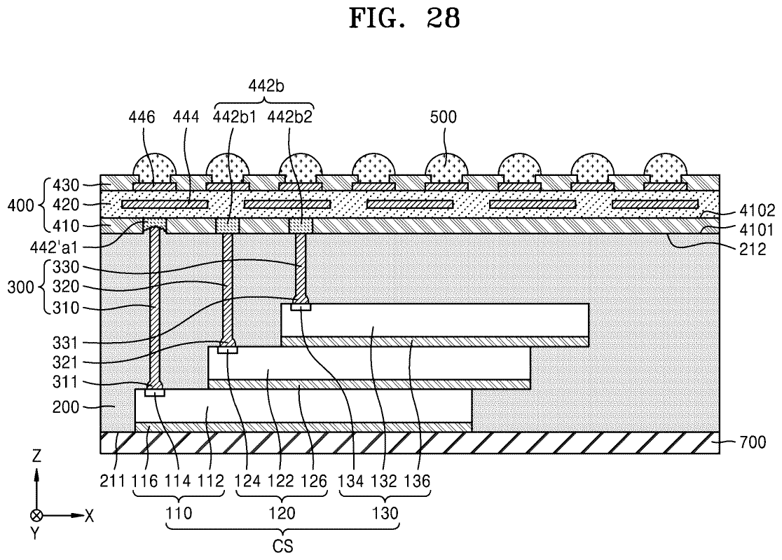

Referring to FIG. 28, after manufacturing the wiring structure 400, the wiring structure 400 may be attached onto the second surface 212 of the encapsulation layer 200 shown in FIG. 19.

When the wiring structure 400 is attached onto the second surface 212 of the encapsulation layer 200, the first and second conductive pads 442′a1, 442b1, and 442b2 of the wiring structure 400 may be aligned with the first to third bonding wires 310, 320, and 330, the other end of the first bonding wire 310 may be in contact with the first conductive pad 442′a1, the other end of the second bonding wire 320 may be in contact with the second conductive pad 442b1, and the other end of the third bonding wire 330 may be in contact with the second conductive pad 442b2.

Thereafter, the external connection terminal 500 may be attached onto the external connection pad 446 exposed on the second photosensitive resist layer 430 of the wiring structure 400. The external connection terminal 500 may be, for example, a solder ball or a bump. When the external connection terminal 500 is attached thereto, the semiconductor package 10a as shown in FIG. 28 may be completed.

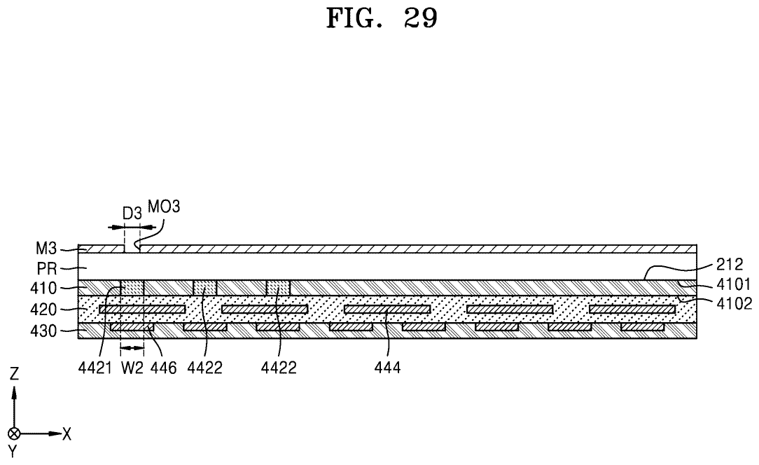

FIGS. 29 to 32 are cross-sectional views sequentially illustrating a process of manufacturing a semiconductor package, according to some example embodiments.

FIG. 29 is a cross-sectional view corresponding to FIG. 21. Therefore, the description made above with reference to FIG. 20 is omitted herein.

Referring to FIG. 29, the photoresist PR may be formed on the first photosensitive resist layer 410. A mask M3 may be provided on the photoresist PR. An opening MO3 of the mask M3 may have a diameter D3 that is less than the diameter W2 of the metal pattern 4421.

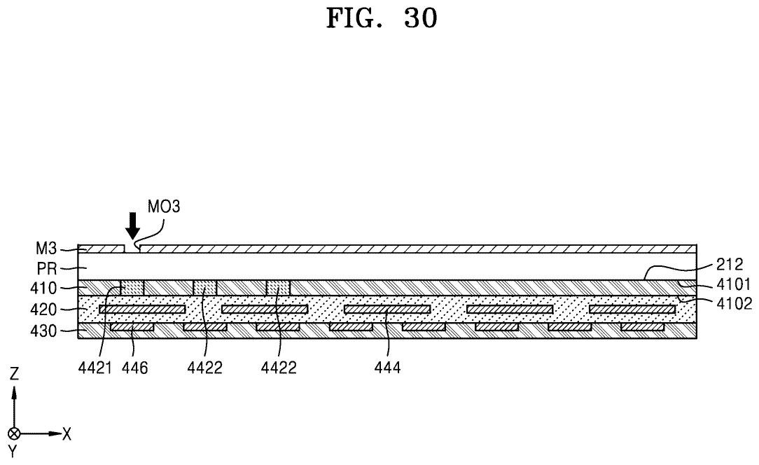

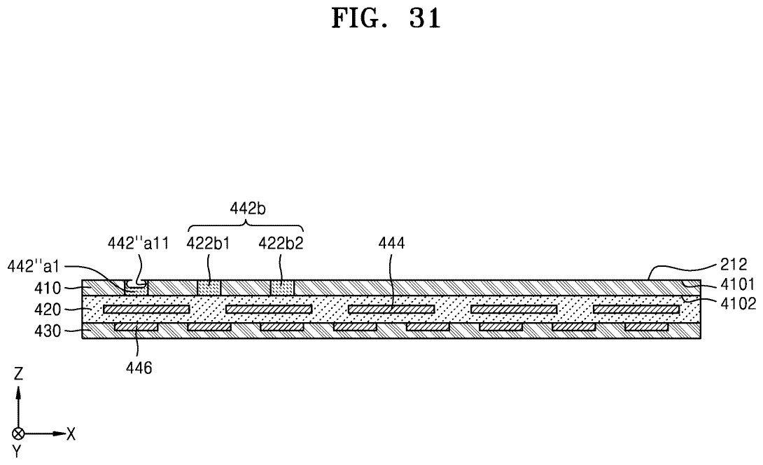

Referring to FIGS. 30 and 31, plasma wet etching may be performed. The undercut 442″a11 may be formed in the metal pattern 4421 by plasma wet etching. The undercut 442″a11 may be formed by etching the metal pattern 4421 by an isotropic etching reaction through chemical wet etching.

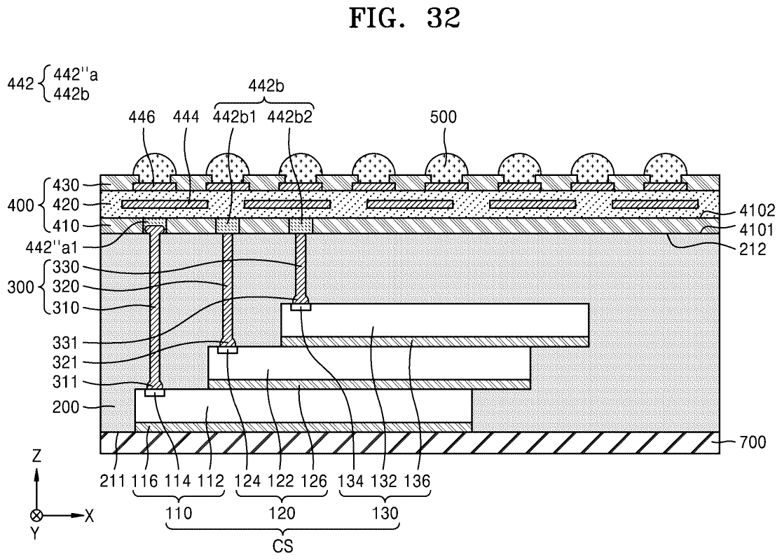

Referring to FIG. 32, after manufacturing the wiring structure 400, the wiring structure 400 may be attached onto the second surface 212 of the encapsulation layer 200 shown in FIG. 19.

When the wiring structure 400 is attached onto the second surface 212 of the encapsulation layer 200, the first and second conductive pads 442″a1, 442b1, and 442b2 of the wiring structure 400 may be aligned with the first to third bonding wires 310, 320, and 330, the other end of the first bonding wire 310 may be in contact with the first conductive pad 442″a1, the other end of the second bonding wire 320 may be in contact with the second conductive pad 442b1, and the other end of the third bonding wire 330 may be in contact with the second conductive pad 442b2.

Thereafter, the external connection terminal 500 may be attached onto the external connection pad 446 exposed on the second photosensitive resist layer 430 of the wiring structure 400. The external connection terminal 500 may be, for example, a solder ball or a bump. When the external connection terminal 500 is attached thereto, the semiconductor package 10b as shown in FIG. 32 may be completed.

While the inventive concepts have been particularly shown and described with reference to some example embodiments thereof, it will be understood that various changes in form and details may be made therein without departing from the spirit and scope of the following claims.

What is claimed is:

1. A semiconductor package comprising:
a semiconductor die stack stacked in a staircase shape;
a wiring structure facing one surface of the semiconductor die stack, the wiring structure comprising a conductive pad facing the semiconductor die stack; and
a bonding wire connecting the semiconductor die stack to the conductive pad,
wherein the wiring structure comprises a wiring structure upper surface and a wiring structure lower surface, the wiring structure upper surface facing the one surface of the semiconductor die stack, and the wiring structure lower surface opposite the wiring structure upper surface, and the wiring structure upper surface extends along a virtual plane,
the conductive pad comprises a conductive pad surface facing the one surface of the semiconductor die stack, and
the conductive pad surface is separated from the virtual plane extending in a direction perpendicular to the conductive pad surface.

2. The semiconductor package of claim 1, wherein a distance from the wiring structure lower surface to the conductive pad surface is less than a distance from the wiring structure lower surface to the wiring structure upper surface.

3. The semiconductor package of claim 1, wherein the conductive pad surface has a recessed shape.

4. The semiconductor package of claim 3, wherein the conductive pad surface has roughness.

5. The semiconductor package of claim 1, wherein the conductive pad has an undercut.

6. The semiconductor package of claim 5, wherein one end of the bonding wire is inside of the undercut.

7. The semiconductor package of claim 1, wherein
the wiring structure has a plurality of conductive pads, and the plurality of conductive pads are grouped into a first conductive pad group and a second conductive pad group,
first conductive pads of the first conductive pad group correspond to a semiconductor die from among the semiconductor die stack that is at a greatest distance away from the wiring structure upper surface,
each of second conductive pads belonging to the second conductive pad group other than the first conductive pad group among the plurality of conductive pads comprises a second conductive pad surface facing a bottom surface of the semiconductor die stack,
each of the first conductive pads comprises a first conductive pad surface facing the bottom surface of the semiconductor die stack, and
the first conductive pad surface is separated from the virtual plane extending in a direction perpendicular to the first conductive pad surface.

8. The semiconductor package of claim 7, wherein the second conductive pad surface is coplanar with the virtual plane.

9. The semiconductor package of claim 7, wherein the second conductive pad surface is separated from the virtual plane in a direction perpendicular to the second conductive pad surface.

10. The semiconductor package of claim 1, wherein a longitudinal direction of the bonding wire is perpendicular to the one surface of the semiconductor die stack.

11. The semiconductor package of claim 1, further comprising an encapsulation layer sealing the semiconductor die stack,
wherein the encapsulation layer has
a first encapsulation layer surface coplanar with another surface of the semiconductor die stack, the another surface of the semiconductor die stack being opposite the one surface of the semiconductor die stack, and
a second encapsulation layer surface opposite the first encapsulation layer surface, and the second encapsulation layer surface being in contact with the wiring structure upper surface.

12. A semiconductor package comprising:
a semiconductor die stack having a plurality of semiconductor dies stacked in a staircase shape in a first horizontal direction;
an upper semiconductor die stack on the semiconductor die stack, the upper semiconductor die stack having a plurality of upper semiconductor dies stacked in a staircase shape in a second horizontal direction that is opposite the first horizontal direction;
a wiring structure facing one surface of the semiconductor die stack, the wiring structure comprising conductive pads facing the semiconductor die stack; and
bonding wires connecting the upper semiconductor die stack and the semiconductor die stack to the conductive pads,
wherein the wiring structure comprises a wiring structure upper surface and a wiring structure lower surface, the wiring structure upper surface facing the one surface of the semiconductor die stack, and the wiring structure lower surface opposite the wiring structure upper surface, and the wiring structure upper surface extends along a virtual plane,
the conductive pads comprise a conductive pad surface facing one of the upper semiconductor die stack or the semiconductor die stack, and
the conductive pad surface is separated from the virtual plane in a direction perpendicular to the conductive pad surface.

13. The semiconductor package of claim 12, wherein the conductive pad surface is recessed.

14. The semiconductor package of claim 12, wherein the conductive pad surface has roughness.

15. The semiconductor package of claim 12, wherein the conductive pads have an undercut therein.

16. The semiconductor package of claim 12, further comprising an encapsulation layer sealing the upper semiconductor die stack and the semiconductor die stack,
wherein the encapsulation layer has
a first encapsulation layer surface coplanar with another surface of the semiconductor die stack, the another surface of the semiconductor die stack being opposite the one surface of the semiconductor die stack, and
a second encapsulation layer surface opposite the first encapsulation layer surface, and the second encapsulation layer surface being in contact with the wiring structure upper surface.

17. A semiconductor package comprising:
a semiconductor die stack stacked in a staircase shape;
an encapsulation layer sealing the semiconductor die stack;
a wiring structure facing one surface of the semiconductor die stack, the wiring structure comprising a plurality of conductive pads facing the semiconductor die stack; and
a bonding wire connecting the semiconductor die stack to a conductive pad from among the plurality of conductive pads,
wherein the wiring structure comprises a wiring structure upper surface and a wiring structure lower surface, the wiring structure upper surface facing the one surface of the semiconductor die stack, and the wiring structure lower surface opposite the wiring structure upper surface,
the encapsulation layer comprises
a first encapsulation layer surface coplanar with another surface of the semiconductor die stack, the another surface of the semiconductor die stack being opposite the one surface of the semiconductor die stack, and
a second encapsulation layer surface opposite the first encapsulation layer surface, the second encapsulation layer surface being in contact with the wiring structure upper surface,
the conductive pad comprises a conductive pad surface facing the second encapsulation layer surface,
the plurality of conductive pads are grouped into a first conductive pad group and a second conductive pad group, first conductive pads of the first conductive pad group correspond to a semiconductor die from among the semiconductor die stack at a greatest distance away from the wiring structure upper surface,
each of second conductive pads of the second conductive pad group other than the first conductive pad group among the plurality of conductive pads comprises a second conductive pad surface facing a bottom surface of the semiconductor die stack,
each of the first conductive pads comprises a first conductive pad surface facing the bottom surface of the semiconductor die stack, and
the first conductive pad surface is separated from a virtual plane in a direction perpendicular to the first conductive pad surface.

18. The semiconductor package of claim 17, wherein the second conductive pad surface is coplanar with the virtual plane.

19. The semiconductor package of claim 17, wherein the second conductive pad surface is separated from the virtual plane in a direction perpendicular to the second conductive pad surface.

20. The semiconductor package of claim 17, wherein the first conductive pad surface is recessed.
